(19) United States
(12) Patent Application Publication
(10) Pub. No.: US 2012/0068282 A1
(43) Pub. Date: Mar. 22, 2012

(54) SEMICONDUCTOR DEVICE AND MANUFACTURING METHOD OF THE SAME

(75) Inventors: Masamichi MATSUOKA, Kanagawa (JP); Tatsuya Fukumura, Kanagawa (JP); Fumihiko Nitta, Kanagawa (JP)

(73) Assignee: Renesas Electronics Corporation

(21) Appl. No.: 13/188,888

(22) Filed: Jul. 22, 2011

(30) Foreign Application Priority Data
Sep. 22, 2010 (JP) 2010-211847

(51) Int. Cl. H01L 29/82; H01L 21/8246

(52) U.S. Cl. 257/421; 438/3; 257/E21.665; 257/E29.323

(57) ABSTRACT

To provide a semiconductor device capable of suppressing a short circuit between an upper conductive element and a lower conductive element which constitute an MRAM, and a manufacturing method of the same.

There are provided a semiconductor substrate having a main surface, a magnetic tunnel junction structure located over the main surface of the semiconductor substrate and including a pin layer, a tunnel insulating layer, and a free layer, a lower insulating layer contacting a lower side surface of the magnetic tunnel junction structure, a sidewall insulating layer located over the lower insulating layer in contact with the upper side surface of the magnetic tunnel junction structure, and exposing the top surface of the magnetic tunnel junction structure, and a conductive layer contacting the top surface of the magnetic tunnel junction structure exposed from the sidewall insulating layer.

### CROSS-REFERENCE TO RELATED APPLICATION

The disclosure of Japanese Patent Application No. 2010-211847 filed on Sep. 22, 2010 including the specification, drawings and abstract is incorporated herein by reference in its entirety.

### BACKGROUND

The present invention relates to a semiconductor device and a manufacturing method of the same and, more particularly, to a semiconductor device having a magnetoresistive element and a manufacturing method of the same.

As a semiconductor device, such as a semiconductor integrated circuit for storage, conventionally, a DRAM (Dynamic Random Access Memory) and SRAM (Static Random Access Memory) are widely used. On the other hand, an MRAM (Magnetic Random Access Memory) is a device to store information using magnetism and has characteristics excellent compared to other memory technology in the points of high-speed operation, rewritability, nonvolatility, etc.

Accompanying the miniaturization of the MRAM, there is an apprehension about the possibility of occurrence of an electrical short circuit between elements constituting the MRAM. A method of suppressing the electrical short circuit in the MRAM is disclosed in, for example, Japanese Patent Laid-Open No. 2006-295198 (hereinafter, referred to as “Patent Document 1”) and Japanese Patent Laid-Open No. 2007-73971 (hereinafter, referred to as “Patent Document 2”).

Further, technology to suppress a short circuit between a gate electrode and a bit line arranged between a plurality of the gate electrodes constituting a semiconductor device is disclosed in, for example, Japanese Patent Laid-Open No. 1996-335633 (hereinafter, referred to as “Patent Document 3”).

### SUMMARY

Among the MRAMs, a so-called STT (Spin Transfer Torque)-MRAM, in which the direction of magnetization changes according to the direction of an electric current flowing through the memory, is being reduced in size as the miniaturization of a semiconductor element advances. In the STT-MRAM, the write current is reduced as the size of a magnetic tunnel junction (MTJ) element, which is an MRAM element, is reduced, and therefore, the plane size of the magnetic tunnel junction element is formed as small as possible. Hence, the plane size of the magnetic tunnel junction element is smaller than the diameter of a hole through which an upper electrode is led out. Therefore, such a structure is employed in which an upper electrode arranged at the upper part of the magnetic tunnel junction element is coupled directly with a wiring at the upper part without forming a hole that reaches the magnetic tunnel junction element.

In this case, the wiring at the upper part is formed in a wiring groove after, for example, a laminated structure constituting the magnetic tunnel junction element is formed, a part of an interlayer insulating layer at the upper part of the magnetic tunnel junction element is removed, and the wiring groove that reaches the magnetic tunnel junction element is formed.

Normally, in the magnetic tunnel junction element, layers to be magnetized, called a pin layer and a free layer, are arranged vertically with a tunnel insulating layer sandwiched in between. Here, if a groove is formed for wiring at the upper part of the magnetic tunnel junction element, it is difficult to control the depth of the groove and variations occur in each step, and therefore, a relative relationship in the longitudinal direction (vertical direction) between the bottom part of the wiring groove and the magnetic tunnel junction element varies in the wafer plane. Here, because of the variations, for example, if a wiring groove is formed such that its depth reaches both the free layer and the pin layer, when a wiring is formed in the wiring groove, there is a possibility that the free layer and the pin layer short-circuit due to the wiring. If such a short circuit occurs, it no longer works as an MRAM element, and therefore, yields are reduced.

In Patent Document 1 and Patent Document 2, it is not examined the exposure of both the pin layer and the free layer from a groove due to the variations in the groove depth when forming the groove that reaches the magnetic tunnel junction element in the interlayer insulating layer. In Patent Document 3, the MRAM structure comprising the pin layer and the free layer is not at all disclosed.

The present invention has been made in view of the above circumstances and provides a semiconductor device capable of suppressing a short circuit between an upper conductive element and a lower conductive element both constituting an MRAM, and a manufacturing method of the same.

A semiconductor device according to an embodiment of the present invention comprises the following configuration. The semiconductor device comprises a semiconductor substrate having a main surface, a magnetoresistive element located over the main surface of the semiconductor substrate and including a pin layer, a tunnel insulating layer, and a free layer, a lower insulating layer contacting a lower side surface of the magnetoresistive element, a sidewall insulating layer located over the lower insulating layer in contact with an upper side surface of the magnetoresistive element and exposing a top surface of the magnetoresistive element, and a conductive layer contacting the top surface of the magnetoresistive element exposed from the sidewall insulating layer.

A manufacturing method of a semiconductor device according to an embodiment of the present invention comprises the following steps. First, a semiconductor substrate having a main surface is provided. A magnetoresistive element located over the main surface of the semiconductor substrate and including a pin layer, a tunnel insulating layer, and a free layer is formed. A first insulating layer is formed so as to cover the magnetoresistive element. The first insulating layer is removed by an amount corresponding to a predetermined thickness and the top surface and the upper side surface of the magnetoresistive element are exposed from the first insulating layer. A second insulating layer is formed so as to cover the top surface and the upper side surface of the magnetoresistive element exposed from the first insulating layer. By etching the second insulating layer until the top surface of the magnetoresistive element is exposed, a sidewall insulating layer contacting the upper side surface of the magnetoresistive element is formed from the second insulating layer. A conductive layer is formed so as to contact the top surface of the magnetoresistive element exposed from the sidewall insulating layer.

According to the present embodiment, the upper side surface of the magnetoresistive element is covered with the sidewall insulating layer and the lower side surface is covered with the lower insulating layer. Hence, the possibility that the pin layer and the free layer constituting the magnetoresistive element are short-circuited by the conductive layer is reduced, and a semiconductor device having improved yields is provided.

According to the manufacturing method of the present embodiment, the first insulating layer is removed by an amount corresponding to a predetermined thickness in order to form the conductive layer in contact with the top surface of the magnetoresistive element. Even if the thickness to be removed varies, the possibility that the pin layer and the free layer of the magnetoresistive element short-circuit by the conductive layer is reduced. Thus, the yields of the semiconductor device are improved.

### BRIEF DESCRIPTION OF THE DRAWINGS

FIG. 1 is a general plan view of a semiconductor device according to a first embodiment of the present invention;

FIG. 2 is a general circuit diagram of the semiconductor device according to the first embodiment of the present invention;

FIG. 3 is a schematic structural perspective view showing a relationship of arrangement between magnetoresistive elements and bit lines in an STT-MRAM memory cell according to the first embodiment of the present invention;

FIG. 4 is a plan view showing a layout of the STT-MRAM memory cell according to the first embodiment of the present invention;

FIG. 5 is a sectional view showing memory cells and peripheral circuits in the STT-MRAM in the first embodiment of the present invention;

FIG. 6 is an enlarged sectional view showing a region “VI” surrounded by a dotted line in FIG. 5 in more detail;

FIG. 7 is a schematic sectional view of a part along a VII-VII line in FIG. 6;

FIG. 8 is an enlarged sectional view showing a modified example different from FIG. 6 in the first embodiment of the present invention;

FIG. 9 is a schematic sectional view of a part along a IX-IX line in FIG. 8;

FIG. 10 is a schematic structural perspective view showing a relationship of arrangement between magnetoresistive elements and bit lines in a normal MRAM memory cell as a modified example of the first embodiment of the present invention;

FIG. 11 is a plan view showing a layout of the normal MRAM memory cell according to the first embodiment of the present invention;

FIG. 12 is a sectional view showing memory cells and peripheral circuits in the normal MRAM according to the first embodiment of the present invention;

FIG. 13 is a partial sectional perspective view showing a step of a manufacturing method of a memory cell in the STT-MRAM in the first embodiment of the present invention;

FIG. 14 is a partial sectional perspective view showing a step performed after the step shown in FIG. 13 in the first embodiment of the present invention;

FIG. 15 is a partial sectional perspective view showing a step performed after the step shown in FIG. 14 in the first embodiment of the present invention;

FIG. 16 is a partial sectional perspective view showing a step performed after the step shown in FIG. 15 in the first embodiment of the present invention;

FIG. 17 is a partial sectional perspective view showing a step performed after the step shown in FIG. 16 in the first embodiment of the present invention;

FIG. 18 is a partial sectional perspective view showing a step performed after the step shown in FIG. 17 in the first embodiment of the present invention;

FIG. 19 is a partial sectional perspective view showing a step performed after the step shown in FIG. 18 in the first embodiment of the present invention;

FIG. 20 is a partial sectional perspective view showing a step performed after the step shown in FIG. 19 in the first embodiment of the present invention;

FIG. 21(A) is a partial sectional perspective view in a bit-line direction of a memory cell, showing a step performed after the step shown in FIG. 20 in the first embodiment of the present invention;

FIG. 21(B) is a partial sectional perspective view in a direction perpendicular to the bit-line direction of the memory cell in FIG. 21(A);

FIG. 22(A) is a partial sectional perspective view in a bit-line direction of the memory cell, showing a step performed after the step shown in FIGS. 21(A) and 21(B) in the first embodiment of the present invention;

FIG. 22(B) is a partial sectional perspective view in a direction perpendicular to the bit-line direction of the memory cell in FIG. 22(A);

FIG. 23(A) is a partial sectional perspective view in a bit-line direction of the memory cell, showing a step performed after the step shown in FIGS. 22(A) and 22(B) in the first embodiment of the present invention;

FIG. 23(B) is a partial sectional perspective view in a direction perpendicular to the bit-line direction of the memory cell in FIG. 23(A);

FIG. 24(A) is a partial sectional perspective view in a bit-line direction of the memory cell, showing a step performed after the step shown in FIGS. 23(A) and 23(B) in the first embodiment of the present invention;

FIG. 24(B) is a partial sectional perspective view in a direction perpendicular to the bit-line direction of the memory cell in FIG. 24(A);

FIG. 25(A) is a partial sectional perspective view in a bit-line direction of the memory cell, showing a step performed after the step shown in FIGS. 24(A) and 24(B) in the first embodiment of the present invention;

FIG. 25(B) is a partial sectional perspective view in a direction perpendicular to the bit-line direction of the memory cell in FIG. 25(A);

FIG. 26(A) is a partial sectional perspective view in a bit-line direction of the memory cell, showing a step performed after the step shown in FIGS. 25(A) and 25(B) in the first embodiment of the present invention;

FIG. 26(B) is a partial sectional perspective view in a direction perpendicular to the bit-line direction of the memory cell in FIG. 26(A);

FIG. 27(A) is a partial sectional perspective view in a bit-line direction of the memory cell, showing a step performed after the step shown in FIGS. 26(A) and 26(B) in the first embodiment of the present invention;

FIG. 27(B) is a partial sectional perspective view in a direction perpendicular to the bit-line direction of the memory cell in FIG. 27(A);

FIG. 28 is a sectional view showing memory cells and peripheral circuits in an STT-MRAM in a second embodiment of the present invention;

FIG. 29 is an enlarged sectional view showing a region “XXIX” surrounded by a dotted line in FIG. 28 in more detail;

FIG. 30 is a schematic sectional view of a part along a XXX-XXX line in FIG. 29;

FIG. 31 is an enlarged sectional view showing a configuration different from that in FIG. 29 as a reference example of the second embodiment of the present invention;

FIG. 32 is a schematic sectional view of a part along a XXXII-XXXII line in FIG. 31;

FIG. 33 is a sectional view showing memory cells and peripheral circuits in an STT-MRAM in a third embodiment of the present invention;

FIG. 34 is an enlarged sectional view showing a region “XXXIV” surrounded by a dotted line in FIG. 33 in more detail;

FIG. 35 is a schematic sectional view of a part along a XXXV-XXXV line in FIG. 34;

FIG. 36(A) is a partial sectional perspective view in a bit-line direction of a memory cell, showing a step of a manufacturing method of a memory cell in the STT-MRAM in the third embodiment of the present invention;

FIG. 36(B) is a partial sectional perspective view in a direction perpendicular to the bit-line direction of the memory cell in FIG. 36(A);

FIG. 37(A) is a partial sectional perspective view in a bit-line direction of the memory cell, showing a step performed after the step shown in FIGS. 36(A) and 36(B) in the third embodiment of the present invention;

FIG. 37(B) is a partial sectional perspective view in a direction perpendicular to the bit-line direction of the memory cell in FIG. 37(A);

FIG. 38(A) is a partial sectional perspective view in a bit-line direction of the memory cell, showing a step performed after the step shown in FIGS. 37(A) and 37(B) in the third embodiment of the present invention;

FIG. 38(B) is a partial sectional perspective view in a direction perpendicular to the bit-line direction of the memory cell in FIG. 38(A);

FIG. 39(A) is a partial sectional perspective view in a bit-line direction of the memory cell, showing a step performed after the step shown in FIGS. 38(A) and 38(B) in the third embodiment of the present invention;

FIG. 39(B) is a partial sectional perspective view in a direction perpendicular to the bit-line direction of the memory cell in FIG. 39(A);

FIG. 40(A) is a partial sectional perspective view in a bit-line direction of the memory cell, showing a step performed after the step shown in FIGS. 39(A) and 39(B) in the third embodiment of the present invention;

FIG. 40(B) is a partial sectional perspective view in a direction perpendicular to the bit-line direction of the memory cell in FIG. 40(A);

FIG. 41 is a sectional view showing memory cells and peripheral circuits in an STT-MRAM in a fourth embodiment of the present invention;

FIG. 42 is an enlarged sectional view showing a region “XLII” surrounded by a dotted line in FIG. 41 in more detail.

FIG. 43 is a schematic sectional view of a part along a XLIII-XLIII line in FIG. 42;

FIG. 44(A) is a partial sectional perspective view in a bit-line direction of a memory cell, showing a step of a manufacturing method of a memory cell in the STT-MRAM in the fourth embodiment of the present invention;

FIG. 44(B) is a partial sectional perspective view in a direction perpendicular to the bit-line direction of the memory cell in FIG. 44(A);

FIG. 45(A) is a partial sectional perspective view in a bit-line direction of the memory cell, showing a step performed after the step shown in FIGS. 44(A) and 44(B) in the fourth embodiment of the present invention;

FIG. 45(B) is a partial sectional perspective view in a direction perpendicular to the bit-line direction of the memory cell in FIG. 45(A);

FIG. 46(A) is a partial sectional perspective view in a bit-line direction of the memory cell, showing a step performed after the step shown in FIGS. 45(A) and 45(B) in the fourth embodiment of the present invention;

FIG. 46(B) is a partial sectional perspective view in a direction perpendicular to the bit-line direction of the memory cell in FIG. 46(A);

FIG. 47(A) is a partial sectional perspective view in a bit-line direction of the memory cell, showing a step performed after the step shown in FIGS. 46(A) and 46(B) in the fourth embodiment of the present invention;

FIG. 47(B) is a partial sectional perspective view in a direction perpendicular to the bit-line direction of the memory cell in FIG. 47(A);

FIG. 48(A) is a partial sectional perspective view in a bit-line direction of the memory cell, showing a step performed after the step shown in FIGS. 47(A) and 47(B) in the fourth embodiment of the present invention;

FIG. 48(B) is a partial sectional perspective view in a direction perpendicular to the bit-line direction of the memory cell in FIG. 48(A);

FIG. 49(A) is a partial sectional perspective view in a bit-line direction of the memory cell, showing a step performed after the step shown in FIGS. 48(A) and 48(B) in the fourth embodiment of the present invention;

FIG. 49(B) is a partial sectional perspective view in a direction perpendicular to the bit-line direction of the memory cell in FIG. 49(A);

FIG. 50(A) is a partial sectional perspective view in a bit-line direction of the memory cell, showing a step performed after the step shown in FIGS. 49(A) and 49(B) in the fourth embodiment of the present invention;

FIG. 50(B) is a partial sectional perspective view in a direction perpendicular to the bit-line direction of the memory cell in FIG. 50(A);

FIG. 51(A) is a partial sectional perspective view in a bit-line direction of the memory cell, showing a step performed after the step shown in FIGS. 50(A) and 50(B) in the fourth embodiment of the present invention;

FIG. 51(B) is a partial sectional perspective view in a direction perpendicular to the bit-line direction of the memory cell in FIG. 51(A);

FIG. 52 is a sectional view showing memory cells and peripheral circuits in a normal MRAM in a fifth embodiment of the present invention;

FIG. 53 is an enlarged sectional view showing a region “LIII” surrounded by a dotted line in FIG. 52 in more detail;

FIG. 54 is a schematic sectional view of a part along a LIV-LIV line in FIG. 53;

FIG. 55(A) is a partial sectional perspective view in a bit-line direction of a memory cell, showing a step of a manufacturing method of a memory cell in the normal MRAM in the fifth embodiment of the present invention;

FIG. 55(B) is a partial sectional perspective view in a direction perpendicular to the bit-line direction of the memory cell in FIG. 55(A);

FIG. 56(A) is a partial sectional perspective view in a bit-line direction of the memory cell, showing a step performed after the step shown in FIGS. 55(A) and 55(B) in the fifth embodiment of the present invention;

FIG. 56(B) is a partial sectional perspective view in a direction perpendicular to the bit-line direction of the memory cell in FIG. 56(A);

FIG. 57(A) is a partial sectional perspective view in a bit-line direction of the memory cell, showing a step performed after the step shown in FIGS. 56(A) and 56(B) in the fifth embodiment of the present invention;

FIG. 57(B) is a partial sectional perspective view in a direction perpendicular to the bit-line direction of the memory cell in FIG. 57(A);

FIG. 58(A) is a partial sectional perspective view in a bit-line direction of the memory cell, showing a step performed after the step shown in FIGS. 57(A) and 57(B) in the fifth embodiment of the present invention;

FIG. 58(B) is a partial sectional perspective view in a direction perpendicular to the bit-line direction of the memory cell in FIG. 58(A);

FIG. 59(A) is a partial sectional perspective view in a bit-line direction of the memory cell, showing a step performed after the step shown in FIGS. 58(A) and 58(B) in the fifth embodiment of the present invention;

FIG. 59(B) is a partial sectional perspective view in a direction perpendicular to the bit-line direction of the memory cell in FIG. 59(A);

FIG. 60(A) is a partial sectional perspective view in a bit-line direction of the memory cell, showing a step performed after the step shown in FIGS. 59(A) and 59(B) in the fifth embodiment of the present invention;

FIG. 60(B) is a partial sectional perspective view in a direction perpendicular to the bit-line direction of the memory cell in FIG. 60(A);

FIG. 61 is an enlarged sectional view showing a configuration not comprising an upper electrode in FIG. 6; and

FIG. 62 is an enlarged sectional view showing a configuration not comprising an upper electrode in FIG. 7.

### DETAILED DESCRIPTION

Embodiments of the present invention will be described below based on the drawings.

### First Embodiment

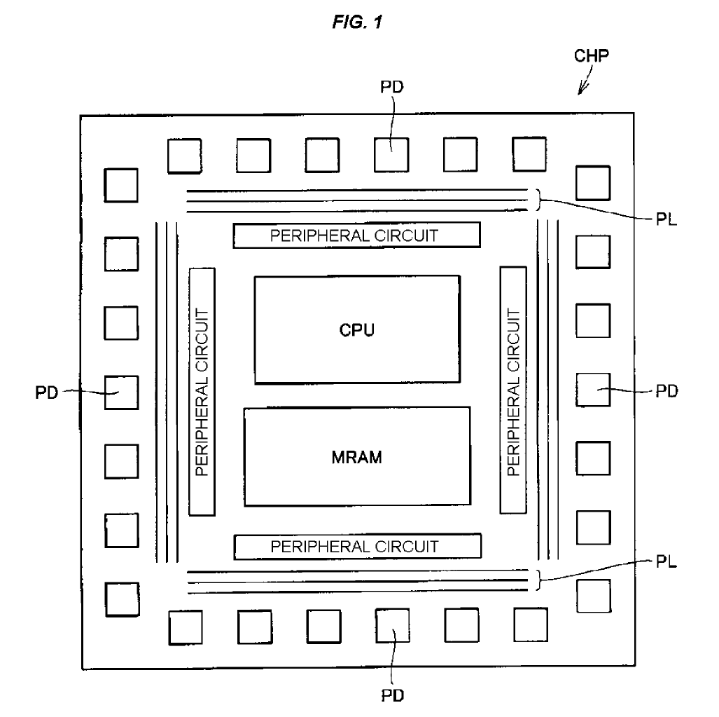

First, a semiconductor device in a chip state will be described using FIG. 1 as a first embodiment.

Referring to FIG. 1, a semiconductor chip CHP in the present embodiment has a CPU (Central Processing Unit), an MRAM, peripheral circuits, and power lines PL. On the periphery of the semiconductor chip CHP, pads PD are arranged.

The CPU is a circuit also called a central processing unit and reads and interprets commands from a storage device and performs various kinds of operation and control based on the commands. Because of this, the CPU is required to be capable of high speed processing.

The MRAM is an element capable of randomly reading and writing stored information by making use of magnetism. The MRAM is a memory element that not only functions as a nonvolatile memory in which a stored state is held even if the power source is turned off but also has a high speed random access function.

The peripheral circuit is a circuit to constitute the system of a semiconductor device together with the CPU and MRAM and includes, for example, a power source circuit, a clock circuit, a reset circuit, etc. The peripheral circuit includes a digital circuit to process a digital signal and an analog circuit to process an analog signal. The analog circuit is a circuit handling a signal of a voltage or current that continuously changes with time, that is, an analog signal and includes, for example, an amplification circuit, conversion circuit, modulation circuit, oscillation circuit, power source circuit, etc.

The power line PL is a line to supply a voltage to operate the CPU, MRAM, and peripheral circuit and includes a power source line, ground line, etc. The CPU, MRAM, and peripheral circuit are coupled to the power line and can operate by the supply of power source from the power line.

The pad PD is an external coupling terminal for input/output to/from a device (circuit) coupled to the outside of the semiconductor chip CHP. Via the pad PD, an input signal is input to the CPU etc. formed on the semiconductor chip CHP. Further, an output signal from the CPU is output to a device (circuit) coupled to the outside of the semiconductor chip CHP via the pad PD.

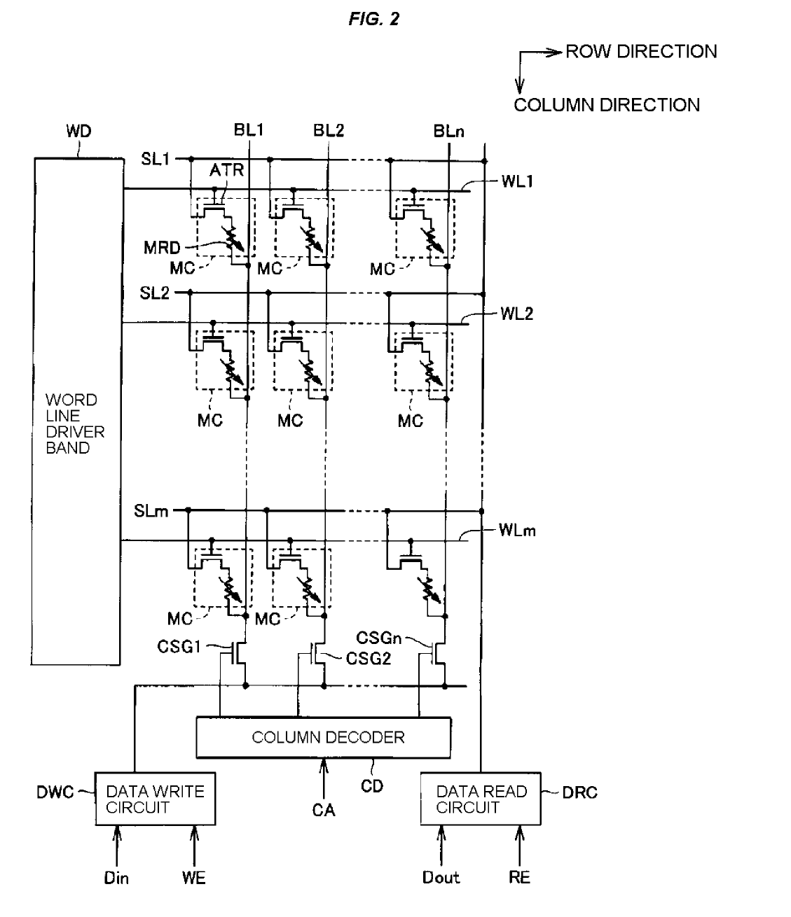

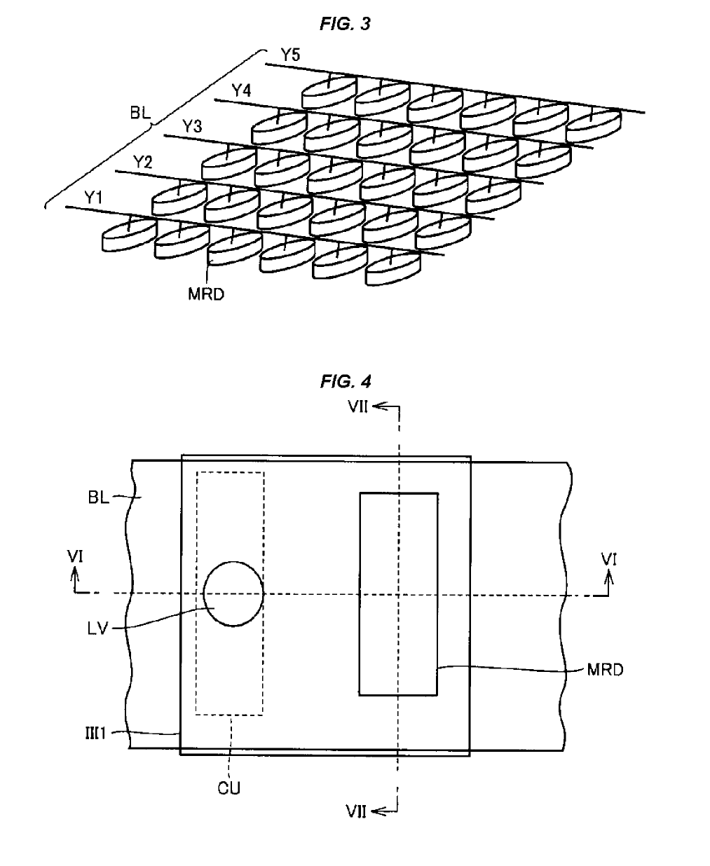

Next, as the MRAM, for example, an equivalent circuit of STT-MRAM is explained using FIG. 2 and FIG. 3.

Referring to FIG. 2, normally, in a circuit constituted by the STT-MRAM, a plurality of memory cells MC of MRAM is arranged in a matrix of n rows in the transverse direction and m columns in the longitudinal direction. That is, the MRAM constitutes a memory cell array including the memory cells MC arranged in an array. Each of the memory cells MC has an access transistor ATR including a magnetoresistive element MRD and MISFET (Metal Insulator Semiconductor Field Effect Transistor).

Along the row of the memory cell array, word lines WL1 to WLm and source lines SL1 to SLm are arranged so as to extend in parallel with each other. On the other hand, bit lines BL1 to BLn are arranged in parallel with each other so as to extend in the longitudinal direction of the memory cell array.

Besides the above, the MRAM has a word line driver band WD electrically coupled with the word lines WL1 to WLm, a data read circuit DRC electrically coupled with the source lines SL1 to SLm, a data write circuit DWC electrically coupled with the bit lines BL1 to BLn via selection transistors GSG1 to GSGn, and a column decoder CD electrically coupled with each gate of the selection transistors GSG1 to GSGn.

The MRAM having a circuit configuration in which there exist lines extending in the transverse direction and the longitudinal direction and the memory cells MC are arranged in an array as described above randomly accesses the specific memory cell MC based on a control signal and an address signal from outside. Then, the MRAM writes input data Dᵢₙ to or reads output data Dₒᵤₜ from the accessed specific memory cell.

Referring to FIG. 3, the MRAM in the present embodiment is, for example, an STT-MRAM, in which bit lines BL (Y1 to Y5) in a plurality of columns (five columns in FIG. 3) are electrically coupled to the magnetoresistive elements MRD. Different from the normal MRAM, to be described later, in the STT-MRAM, no digit line DL is arranged.

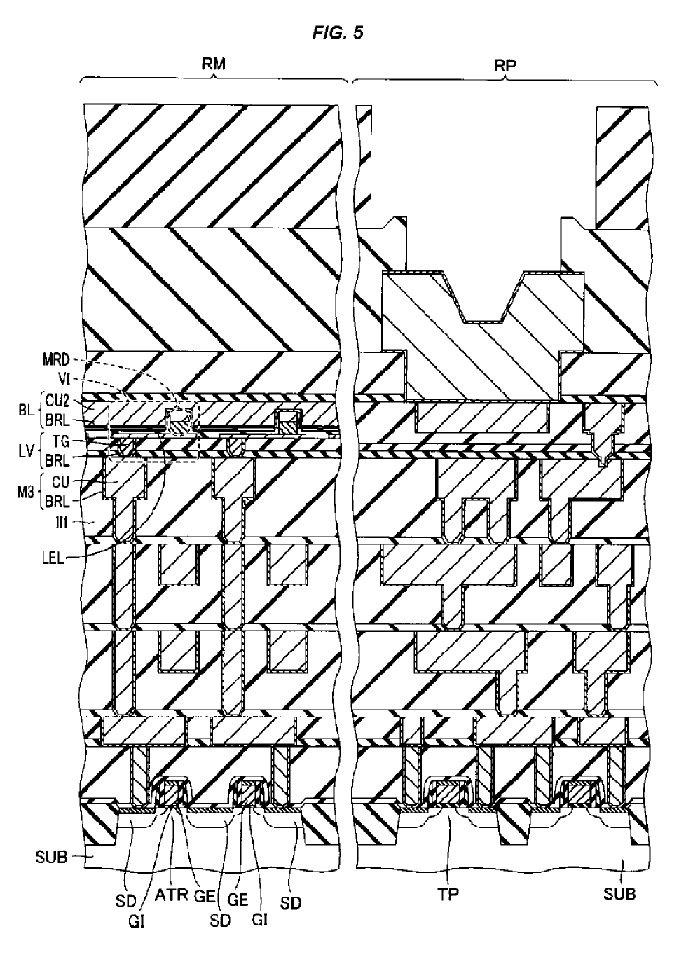

Next, a configuration of an STT-MRAM is explained using FIG. 4 to FIG. 7. FIG. 4 is a plan view of one memory cell of the STT-MRAM and FIG. 5 shows each sectional view of a memory cell region RM and a peripheral circuit region RP of the STT-MRAM.

First, referring to FIG. 5, the memory cell of the STT-MRAM formed in the memory cell region RM has the access transistor ATR and the magnetoresistive element MRD. The access transistor ATR has a pair of source/drain regions SD, which is an impurity diffusion layer including, for example, boron, phosphorus, arsenic, etc., a gate insulating layer GI including a silicon oxide film, and a gate electrode layer GE including a conductor, such as polysilicon and a metal film. The pair of the source/drain regions SD is arranged on the main surface of a semiconductor substrate SUB with a space in between. The gate electrode layer GE is formed over the surface of the semiconductor substrate SUB sandwiched by the pair of the source/drain regions SD via the gate insulating layer GI. The surface of the pair of the source/drain regions SD and the gate electrode layer GE may be silicidated.

The magnetoresistive element MRD is located over the main surface of the semiconductor substrate SUB on which the access transistor ATR is formed via an interlayer insulating layer of a plurality of layers (for example, interlayer insulating layer including four layers of silicon oxide film) II1. The magnetoresistive element MRD is formed so that the undersurface thereof contacts the surface of a lower electrode LEL. The lower electrode LEL is electrically coupled to one of the pair of the source/drain regions SD of the access transistor ATR through a local via LV, a read wiring M3, etc.

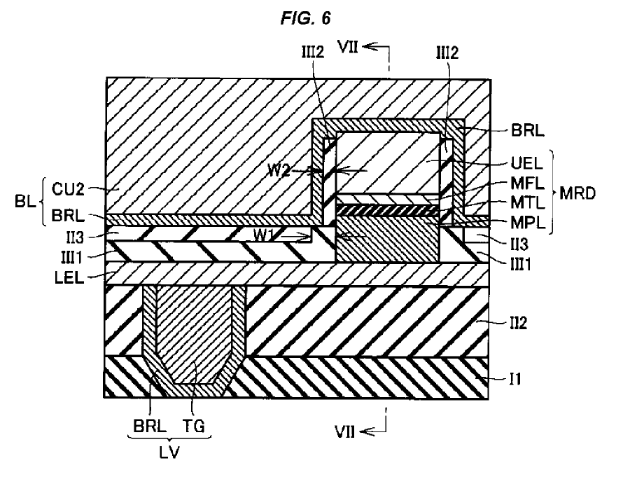

The read wiring M3 includes, for example, a barrier metal BRL and a copper film CU that forms a wiring main body and the barrier metal BRL is formed into an aspect in which the barrier metal BRL covers the undersurface and the side surface of the copper film CU. The local via LV includes, for example, a tungsten film TG and the barrier metal BRL and is formed in a groove provided in a silicon nitride film I1 and a silicon oxide film 112 (FIG. 6).

A bit line BL is formed so as to be electrically coupled to the upper side of the magnetoresistive element MRD. The bit line BL includes, for example, the barrier metal BRL and a copper film CU2 that forms a wiring main body and the barrier metal BRL is formed into an aspect in which the barrier metal BRL covers the undersurface and the side surface of the copper film CU2. Due to this, the magnetoresistive element MRD is arranged between the bit line BL and the lower electrode LEL.

In the peripheral circuit region RP, semiconductor elements, such as a transistor TP, which control the operation etc. of the memory cell (magnetoresistive element) and wirings and vias that electrically couple the semiconductor elements to each other are formed.

FIG. 6 shows a VI-VI section in FIG. 4 and FIG. 7 shows a VII-VII section in FIG. 4. Referring to FIG. 6 and FIG. 7, the magnetoresistive element MRD has a pin layer MPL, a tunnel insulating layer MTL, a free layer MFL, and an upper electrode UEL and has a laminated structure in which, for example, the pin layer MPL, the tunnel insulating layer MTL, the free layer MFL, and the upper electrode UEL are laminated in this order from the bottom. The pin layer MPL is formed so as to contact the top surface of the lower electrode LEL. The upper electrode UEL constitutes the top surface of the magnetoresistive element MRD.

Each of the pin layer MPL and the free layer MFL is a magnetic layer having magnetism. Data is written to the magnetoresistive element MRD when the direction of magnetization of the free layer MFL changes according to the direction of an electric current that passes through the magnetoresistive element MRD.

In each magnetoresistive element MRD, the two magnetic layers (the pin layer MPL and the free layer MFL) are laminated with the tunnel insulating layer MTL interposed in between as described above. The resistance value of the magnetoresistive element MRD changes according to whether the directions of magnetization in the two magnetic layers are the same or opposite to each other. The direction of magnetization of the magnetoresistive element MRD can be changed according to the direction of electric current that flows in a current path from the bit line BL to the access transistor ATR via the magnetoresistive element MRD. Further, by detecting the electric resistance that has changed according to the direction of magnetization of the magnetoresistive element MRD, it is possible to read the direction of magnetization of the magnetoresistive element MRD.

A lower insulating layer III1 is formed so as to contact the lower side surface (for example, the side surface of the pin layer MPL of the magnetoresistive element MRD) of the magnetoresistive element MRD. The lower insulating layer III1 extends over the lower electrode LEL and is formed so as to overlap the position where the lower electrode LEL is formed in a planar view. The lower insulating layer III1 is a protective insulating layer to prevent the magnetoresistive element MRD from being damaged at the time of patterning of the lower electrode LEL.

A sidewall insulating layer III2 is formed located over the lower insulating layer III1 so as to contact the upper side surface of the magnetoresistive element MRD (for example, the side surface of the pin layer MPL, the tunnel insulating layer MTL, the free layer MFL, and the upper electrode UEL of the magnetoresistive element MRD). The sidewall insulating layer III2 does not cover the top surface of the tunnel insulating layer MTL (top surface of the upper electrode UEL) but exposes it.

A width W1 of the part along the sidewall of the magnetoresistive element MRD of the lower insulating layer III1 is greater than a width W2 of the sidewall insulating layer III2 (see FIG. 6). Because of this, there is produced a step at the boundary between the lower insulating layer III1 and the sidewall insulating layer III2 and by the step, it is possible to recognize the boundary between the lower insulating layer III1 and the sidewall insulating layer III2.

Over the lower electrode LEL and the lower insulating layer III1, an interlayer insulating layer II3 is formed. On the top surface of the interlayer insulating layer II3, a wiring groove TR (see FIG. 7) is formed. This wiring groove TR is formed so as to extend right above the magnetoresistive element MRD. Due to this, the top surface and a part of the upper side surface of the magnetoresistive element MRD, the sidewall insulating layer III2, and the lower insulating layer III1 are exposed from the interlayer insulating layer II3. The bottom surface of the wiring groove TR substantially agrees with the boundary surface between the lower insulating layer III1 and the sidewall insulating layer III2 and is located at the height within the range of the thickness of the pin layer MPL. On the sidewall of the wiring groove TR also, the sidewall insulating layer III2 is formed.

Within the wiring groove TR, the bit line (conductive layer) BL, which is a first wiring layer, extending in a direction along the main surface of the semiconductor substrate SUB is formed. The bit line BL contacts the top surface and the part of the upper side surface of the magnetoresistive element MRD exposed from the sidewall insulating layer III2 and due to this, the bit line BL is electrically coupled to the magnetoresistive element MRD. Due to this, a part on the upper end side of the individual magnetoresistive element MRD is arranged so as to cut in the bit line BL. As described above, the bit line BL has, for example, the barrier metal BRL and the copper film CU2 that forms the wiring main body. The barrier metal BRL is formed along the inner wall surface of the wiring groove TR and preferably includes a thin film of, for example, Ta (tantalum), TiN (titanium nitride), etc. The copper film CU2 is formed so as to fill in the inside of the wiring groove TR.

At the lower part of the wiring groove TR (region in which the magnetoresistive element MRD is not arranged in a planar view), preferably, the lower insulating layer III1 is arranged between the interlayer insulating layer II3 and the lower electrode LEL.

Next, the material, film thickness, etc., of each part are explained. Preferably, the lower insulating layer III1 includes, for example, a silicon nitride film as a material different from that of the interlayer insulating layer including a silicon oxide film and preferably, its thickness is not less than 30 nm and not more than 90 nm, and as an example, 60 nm. Preferably, the silicon nitride film of the lower insulating layer III1 is formed under the condition of temperature lower than the normal temperature (lower than 300° C.). By doing so, it is possible to appropriately protect the pin layer MPL and the free layer MFL, which are magnetic layers.

Preferably, the sidewall insulating layer III2 includes a silicon oxide film, a silicon nitride film, a silicon oxynitride film, etc. Further, more preferably, the sidewall insulating layer III2 is made of a material different from that of the interlayer insulating layer including a silicon oxide film.

Preferably, the pin layer MPL is a thin film including a ferromagnetic layer. Specifically, it is preferable for the pin layer MPL to be an elemental metal or an alloy film including one or more kinds of element selected from a group consisting of Ni (nickel), Co (cobalt), Fe (iron), B (boron), Ru (ruthenium). The pin layer MPL is shown schematically as a one-layer structure in FIG. 5 to FIG. 7. However, in general, for the pin layer MPL, a two-layer structure in which a ferromagnetic layer is laminated over an anti ferromagnetic layer or, a four-layer structure or a five-layer structure in which a ferromagnetic layer, a nonmagnetic layer, a ferromagnetic layer are laminated in this order over an antiferromagnetic layer is used. The number of laminated layers or the order of laminated layers is, however, not limited to the above. Preferably, the total thickness of the pin layer MPL is not less than 50 nm and not more than 100 nm.

Preferably, the tunnel insulating layer MTL is an insulating film including any of AlOₓ (aluminum oxide), MgO (magnesium oxide), HfO (hafnium oxide). Preferably, the thickness is not less than 0.5 nm and not more than 2.0 nm and more preferably, not less than 0.6 nm and not more than 1.5 nm.

Preferably, the free layer MFL is a thin film including a ferromagnetic layer. Specifically, it is preferable for the free layer MFL to be an elemental metal or an alloy film including one or more kinds of element selected from a group consisting of Ni (nickel), Co (cobalt), Fe (iron), B (boron), Ru (ruthenium). Further, the free layer MFL may have a configuration in which a plurality of thin films including the alloy of the different material is laminated. Preferably, the total thickness is not less than 2.0 nm and not more than 10 nm and more preferably, not less than 3.0 nm and not more than 9.0 nm.

Preferably, the lower electrode LEL is a metal film including, for example, Ta (tantalum), TaN (tantalum nitride, Ru, TiN (titanium nitride), etc. Further, the lower electrode LEL may have a one-layer structure, however, it may have a structure in which a plurality of thin films including the different material is laminated. Preferably, the thickness of the lower electrode LEL is not less than 10 nm and not more than 70 nm and more preferably, not less than 20 nm and not more than 50 nm (35 nm, as an example).

Preferably, the upper electrode UEL is also a metal film including, for example, Ta, TaN, Ru, TiN, etc., like the lower electrode LEL. The upper electrode UEL may have a one-layer structure, however, it may have a structure in which a plurality of thin films including the different material is laminated. Preferably, the thickness of the upper electrode UEL is, for example, not less than 60 nm and not more than 70 nm. For example, in the case of the upper electrode UEL in which two layers are laminated, preferably, the thickness of the upper electrode UEL at the lower part is, for example, not less than 30 nm and not more than 70 nm and more preferably, not less than 35 nm and not more than 65 nm (60 nm, as an example). Preferably, the thickness of the upper electrode UEL at the upper part is, for example, not less than 5 nm and not more than 100 nm. As an example, there can be supposed the upper electrode UEL having a structure in which a thin film including Ta and having a thickness of 60 nm is laminated over a thin film including Ru and having a thickness of 7.5 nm.

Different from the normal MRAM that is rewritten by an external magnetic field, to be described later, the memory cell MC of the STT-MRAM does not have a digit line (write word line) as a second wiring layer. Further, the bit line BL is not coated with a clad layer having a function to shield a magnetic field.

As described above, if the top surface of the upper electrode UEL is in contact with the bit line BL, the upper electrode UEL and the bit line BL are electrically coupled by a simpler structure. Because no hole is formed between the magnetoresistive element MRD and the bit line BL, it is particularly suitable for the formation of a miniaturized MRAM structure.

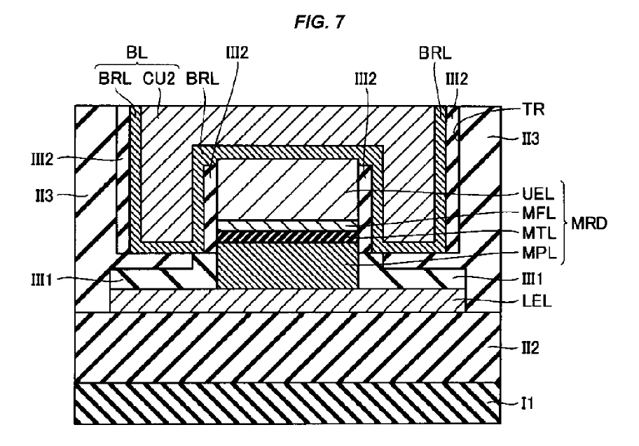

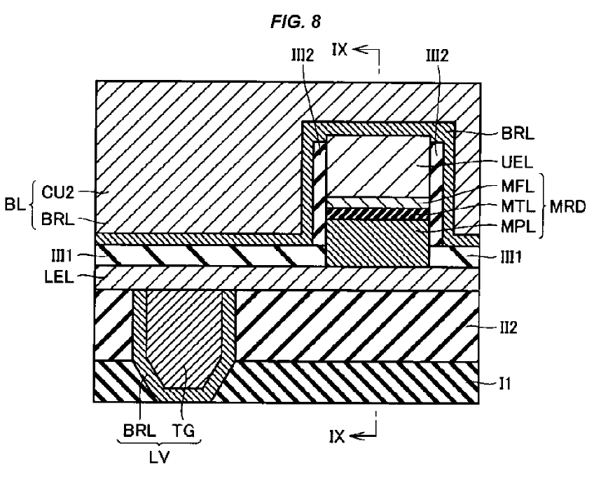

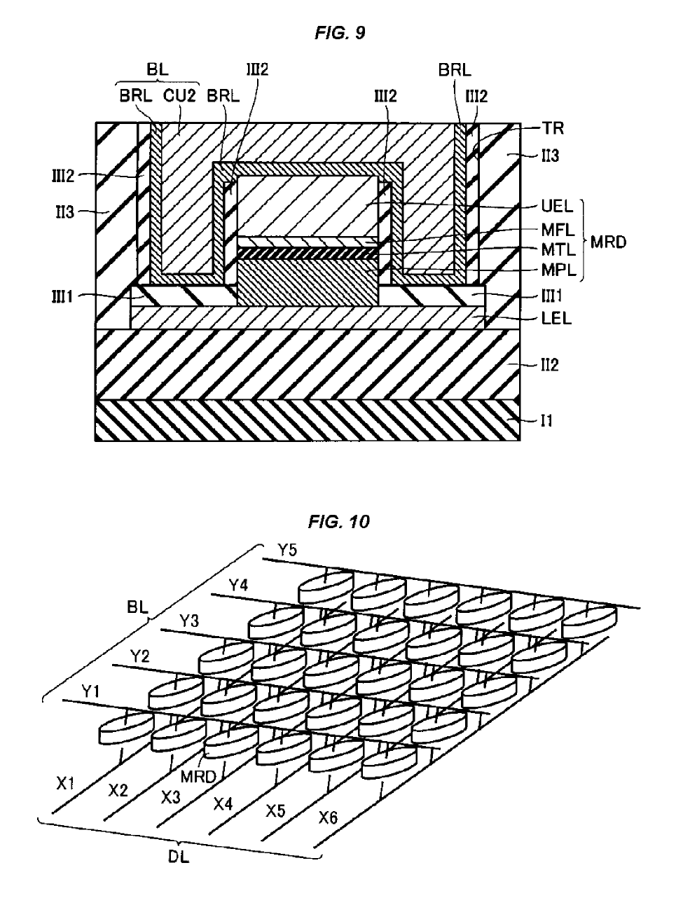

Next, a case where the depth of the wiring groove TR varies due to the variations at the time of manufacture and the wiring groove TR is formed deeper is explained using FIG. 8 and FIG. 9.

FIG. 8 shows a modified example of the VI-VI section in FIG. 4 and FIG. 9 shows a modified example of the VII-VII section in FIG. 4. Referring to FIG. 8 and FIG. 9, when the wiring groove is formed deeper because the depth of the wiring groove TR varies, there is a case where the interlayer insulating layer II3 is not left between the bottom surface of the wiring groove TR and the lower electrode LEL but only the lower insulating layer III1 is left at the lower part of the wiring groove TR (in the region where the magnetoresistive element MRD is not arranged in a planar view). The structure in FIG. 8 and FIG. 9 differs from that in FIG. 6 and FIG. 7 in that the lower part of the bit line BL is in contact with the lower insulating layer III1 and other points are the same as those in FIG. 6 and FIG. 7, and therefore, the same symbol is attached to the same component and its explanation is not repeated.

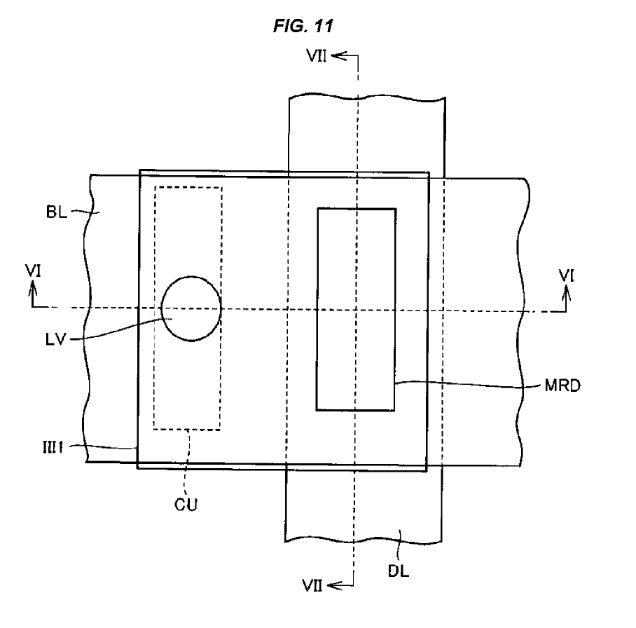

In the above, the STT-MRAM is explained. It is possible to apply the structure of the present embodiment to the normal MRAM that has the digit line (the second wiring layer: write word line) and which is rewritten by an external magnetic field. A structure of the normal MRAM to which the structure of the present embodiment is applied is explained using FIG. 10 and FIG. 11.

Referring to FIG. 10, in the normal MRAM, a plurality of the bit lines BL (Y1 to Y5) (five columns in FIG. 10) is electrically coupled to the magnetoresistive elements MRD and a plurality of the digit lines DL (X1 to X6) (six columns in FIG. 10) extending in the direction substantially perpendicular to the bit line BL is arranged.

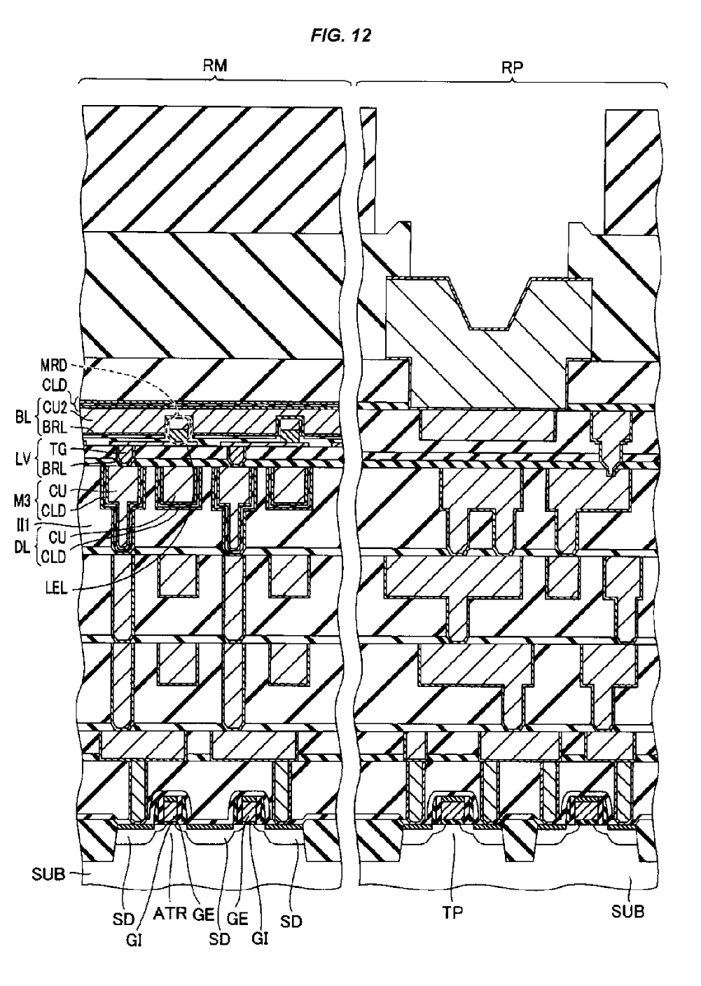

Referring to FIG. 11 and FIG. 12, the structure of the normal MRAM differs from that of the STT-MRAM shown in FIG. 4 and FIG. 5 in that the digit line DL is formed and a clad layer CLD is formed in the digit line DL and the bit line BL, respectively.

In the memory cell region RM, the digit line DL is formed so as to be located in the region right below the magnetoresistive element MRD with the lower electrode LEL, the silicon oxide film 112, and the silicon nitride film I1 sandwiched between the digit line DL and the magnetoresistive element MRD. The digit line DL is manufactured in the same step as the read wiring M3 located right below the local via LV.

Each of the digit line DL and the read wiring M3 has the copper film CU that forms the wiring main body and the clad layer CLD having a function to cover the side surface and the bottom surface of the copper film CU to shield a magnetic field. In the digit line DL located below the magnetoresistive element MRD, the clad layer CLD (second clad layer) is formed into an aspect in which it covers the bottom surface and the sidewall of the copper film CU so that magnetism reaches the magnetoresistive element MRD efficiently. In the read wiring M3 also, the same clad layer CLD is formed. Further, the bit line BL also has the copper film CU that forms the wiring main body and the clad layer CLD having the function to cover the side surface and the top surface of the copper film CU to shield a magnetic field. In the bit line BL located above the magnetoresistive element MRD, the clad layer CLD (first clad layer) is formed into an aspect in which it covers the top surface and the sidewall of the copper film CU so that magnetism reaches the magnetoresistive element MRD efficiently. The clad layer CLD has, for example, a three-layer structure in which a high permeability film MG having a high permeability is sandwiched by two layers of the barrier metals BRL.

The structures other than that of the normal MRAM described above are substantially the same as those of the STT-MRAM shown in FIG. 4 and FIG. 5, and therefore, the same symbol is attached to the same component and its explanation is not repeated. For example, the general sectional views at the parts along the VI-VI line, VII-VII line in FIG. 11 are the same as those in FIG. 6, FIG. 7, respectively.

The structure of the MRAM in FIG. 10 to FIG. 12 differs from that of the STT-MRAM in FIG. 5 to FIG. 7 in the above points. In the normal MRAM also, in the individual magnetoresistive element MRD, the two magnetic layers (the pin layer MPL and the free layer MFL) are laminated with the tunnel insulating layer MTL interposed in between. The resistance value of the magnetoresistive element MRD changes according to whether the directions of magnetization in the two magnetic layers are the same or opposite to each other. The direction of magnetization of the magnetoresistive element MRD can be changed according to a magnetic field that is generated by an electric current flowing through the bit line BL and the digit line DL. Further, by detecting the electric resistance that has changed according to the direction of magnetization of the magnetoresistive element MRD, it is possible to read the direction of magnetization of the magnetoresistive element MRD.

It is preferable to use a soft magnetic material having a high permeability and a very low remanent magnetization as the high permeability film MG constituting the clad layer CLD of the MRAM in FIG. 10 to FIG. 12. Specifically, it is preferable to use an alloy or an amorphous alloy of NiFe (nickel iron), NiFeMo, CoNbZr (cobalt niobium zirconium), CoFeNb, CoFeSiB, CoNbRu, CoNbZrMoCr, CoZrCrMo, etc.

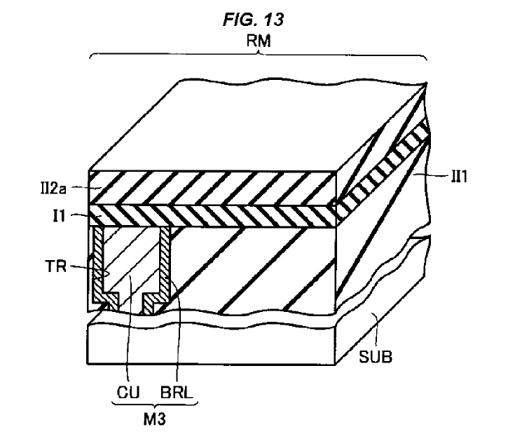

Next, a manufacturing method of the STT-MRAM shown in FIG. 3 to FIG. 7 as a semiconductor device of the present embodiment is explained using FIG. 13 to FIG. 27.

Referring to FIG. 13, after the predetermined transistor, wiring, etc., (see the memory cell region RM in FIG. 5) are formed, the silicon oxide film II1 is formed over the main surface of the semiconductor substrate SUB. In a predetermined region of the silicon oxide film II1, the wiring groove TR is formed. Within the wiring groove TR, the read wiring M3 including the barrier metal BRL and the copper film CU is formed. Next, the silicon nitride film I1 is formed over the silicon oxide film II1 so as to cover the read wiring M3. Over the silicon nitride film I1, a silicon oxide film 112a is formed. In the drawings showing subsequent steps, the semiconductor substrate SUB is omitted for the sake of simplification of the drawings.

Referring to FIG. 14, a local via hole LVH that exposes the read wiring M3 is formed through the silicon oxide film 112a and the silicon nitride film I1. By this processing, the silicon oxide film II2a forms a silicon oxide film II2b. A barrier metal BRLa is formed over the silicon oxide film II2b so as to cover the bottom surface and the sidewall of the local via hole LVH. Next, over the barrier metal BRLa, a tungsten film TGa is formed.

By subjecting the tungsten film TGa and the barrier metal BRLa to chemical mechanical polishing processing, the tungsten film TGa and the barrier metal BRLa are polished and removed until the top surface of the silicon oxide film II2b is exposed (see the position of the alternate long and short dash line).

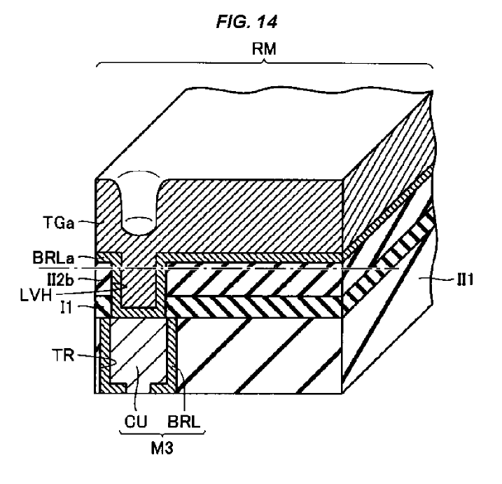

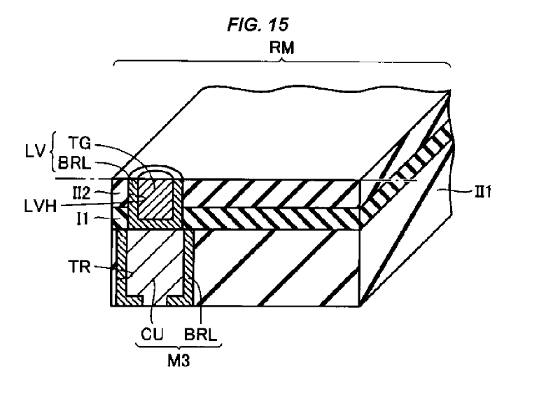

Referring to FIG. 15, by the chemical mechanical polishing processing, the barrier metal BRL and the tungsten film TG are left within the local via hole LVH and the local via LV including the barrier metal BRL and the tungsten film TG is formed. The top surface of the silicon oxide film II2b is flattened and the silicon oxide film II2b forms the silicon oxide film 112.

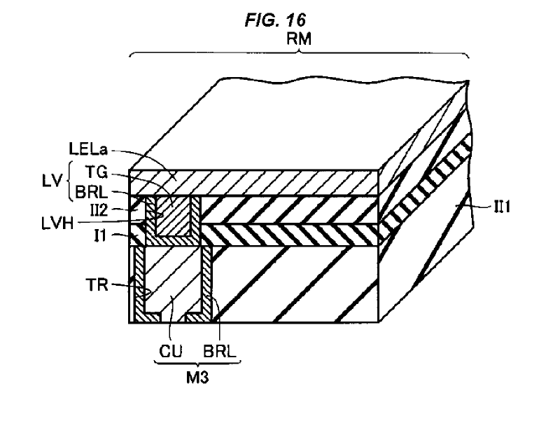

Referring to FIG. 16, over the silicon oxide film 112, a predetermined film LELa that forms a lower electrode is formed.

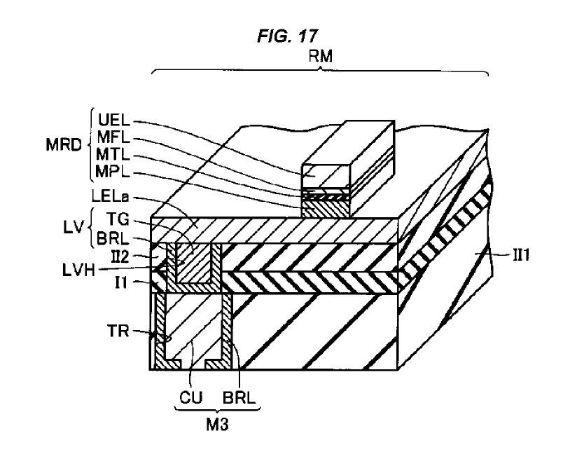

Referring to FIG. 17, over the predetermined film LELa that forms a lower electrode, a predetermined film that forms the pin layer MPL is formed. As the predetermined film, for example, a laminated film including Pt (platinum), Mn (manganese), Ni, Ru, Co, Fe and B is formed. Next, over the predetermined film that forms the pin layer MPL, a predetermined film that forms the tunnel insulating layer MTL is formed.

Next, over a predetermined film that forms the tunnel insulating layer MTL, a predetermined film that forms the free layer MFL is formed. As the predetermined film, an alloy film including at least two metals of, for example, Ni, Fe, Co and B is formed. Next, over a predetermined film that forms the free layer MFL, a predetermined film that forms the upper electrode UEL is formed. As the predetermined film that forms the upper electrode UEL, for example, a structure can be supposed, in which a thin film including Ta and having a thickness of 60 nm is laminated over a thin film including Ru and having a thickness of 7.5 nm.

Over a predetermined film that forms the upper electrode UEL, a resist pattern (not shown schematically) to pattern the magnetoresistive element is formed. Next, etching of a predetermined film that forms the upper electrode UEL is performed under predetermined conditions using the resist pattern as a mask. After this, the resist pattern is removed by, for example, asking etc. After that, using the upper electrode UEL as a mask, etching of the predetermined film that forms the free layer MFL, the predetermined film that forms the tunnel insulating layer MTL, and the predetermined film that forms the pin layer MPL is performed.

By the above-mentioned etching, each layer is patterned and the pin layer MPL, the tunnel insulating layer MTL, the free layer MFL, and the upper electrode UEL are formed and the magnetoresistive element MRD is formed by these layers. In each manufacturing process after the magnetoresistive element MRD is formed, various kinds of processing are performed at temperature of 300° C. or less in order to protect, in particular, the tunnel insulating layer MTL of the magnetoresistive element MRD.

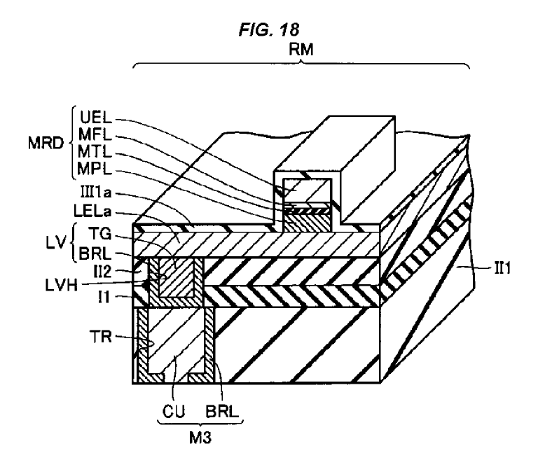

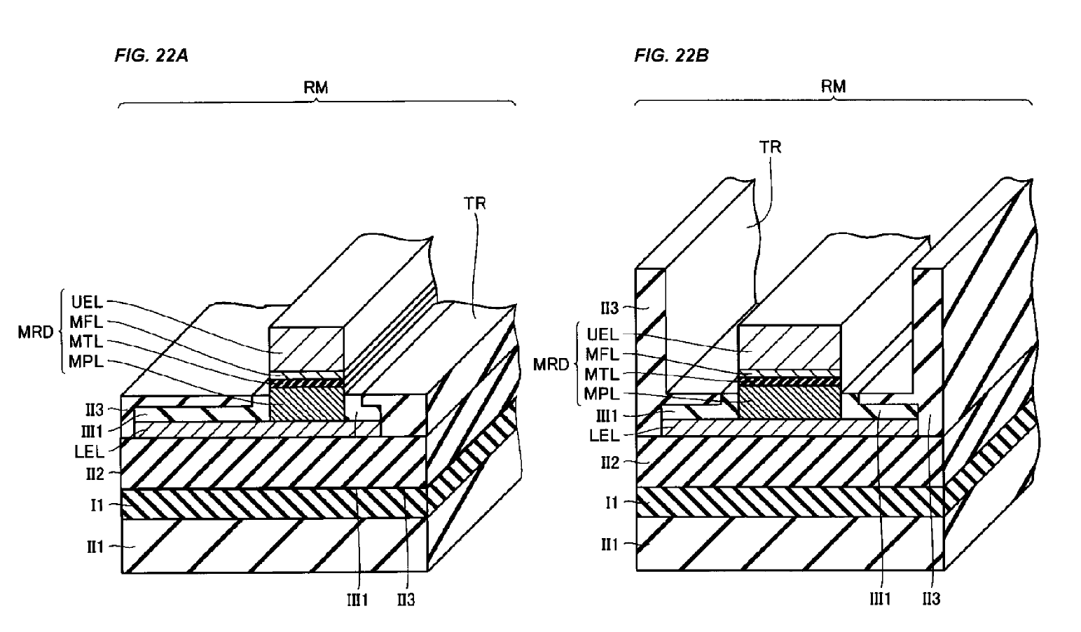

Referring to FIG. 18, a silicon nitride film III1a (third insulating layer) is formed as a protection film over the predetermined film LELa that forms the lower electrode so as to cover the magnetoresistive element MRD. The silicon nitride film III1a is a film that forms the lower insulating layer III1 (see FIG. 22). The silicon nitride film III1a is formed by heating a mixed atmosphere of, for example, the SiH₄ (silane) gas, H₂ (hydrogen) gas, and He (helium) gas to a temperature of 300° C. or less, for example, 275° C., by the CVD (Chemical Vapor Deposition) method.

After this, a resist pattern (not shown schematically) to pattern the predetermined film LELa that forms the lower electrode is formed over the silicon nitride film III1a. Next, using the resist pattern as a mask, etching of the silicon nitride film III1a and the predetermined film LELa that forms the lower electrode is performed under predetermined conditions.

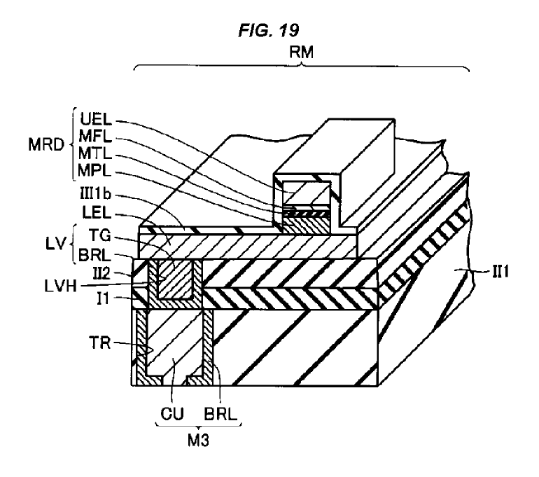

Referring to FIG. 19, by the above-described processing, the predetermined film LELa that forms the lower electrode is patterned and the lower electrode LEL is formed by the predetermined film LELa that forms the lower electrode. Further, the silicon nitride film III1a is patterned to form a silicon nitride film III1b.

After the patterning, the resist pattern is removed by, for example, asking etc. When the resist pattern is removed, the magnetoresistive element MRD is prevented from being damaged because the magnetoresistive element MRD is covered with and protected by the silicon nitride film III1b.

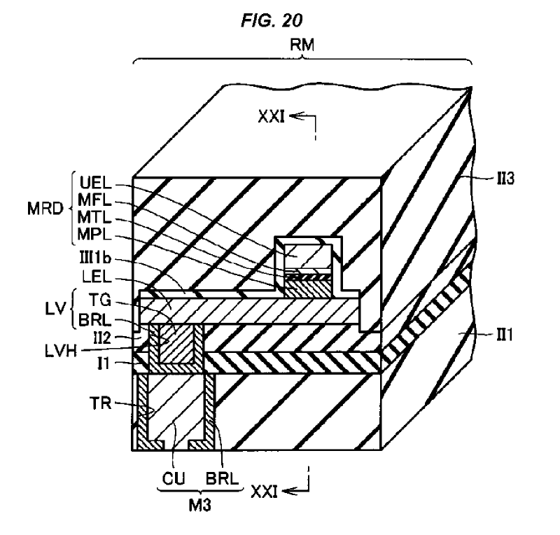

Referring to FIG. 20, the silicon oxide film II3 (first insulating layer) that forms the interlayer insulating layer is formed so as to cover the magnetoresistive element MRD and the silicon nitride film III1b. Here, in particular, a silicon oxide film is formed so as to cover the magnetoresistive element MRD and the silicon nitride film III1a. The silicon oxide film II3 is subjected to chemical mechanical polishing processing. Preferably, the silicon oxide film II3 is formed so that the thickness from its uppermost part to the uppermost surface of the silicon nitride film III1a over the lower electrode LEL is not less than 100 nm and not more than 300 nm. As an example, it can be supposed that the thickness is set to 230 nm.

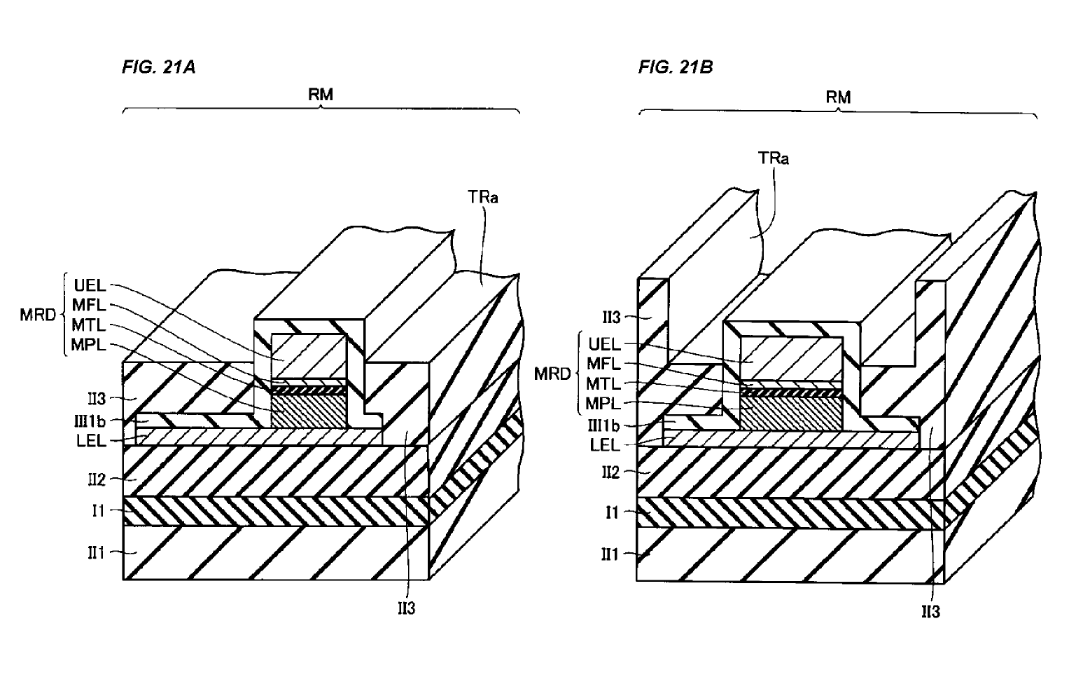

The following FIG. 21 to FIG. 27 show sectional views (A) (corresponding to the VI-VI section in FIG. 4) when viewed in the same direction as that in FIG. 13 to FIG. 20 and sectional views (B) (corresponding to the sectional view along the XXI-XXI line in FIG. 20, the VII-VII section in FIG. 4) when the magnetoresistive element MRD is cut in the direction perpendicular to that in FIG. 13 to FIG. 20.

Referring to FIGS. 21(A) and 21(B), by the photoengraving technique and etching technique, a wiring groove TRa is formed in the interlayer insulating layer II3 including a silicon oxide film. The wiring groove TRa is formed so as to extend in the direction along one of the main surfaces of the semiconductor substrate SUB and extend on the top of the magnetoresistive element MRD. Due to this, from the wiring groove TRa, the surface of the silicon nitride film III1b that covers the top surface and the side surface of the magnetoresistive element MRD is exposed.

Referring to FIGS. 22(A) and 22(B), by the above-mentioned etching, the part of the silicon nitride film III1b exposed from the wiring groove TRa is removed by etching and the upper side surface and the top surface of the magnetoresistive element MRD are exposed. At the time of the etching, the bottom part of the wiring groove TRa is scraped by etching and the wiring groove TRa becomes deeper and forms the wiring groove TR. As an example, it can be supposed that the wiring groove TR has a thickness of 200 nm. At this time, due to the variations in each step etc., there is a case where not only the side surface of the free layer MFL and the tunnel insulating layer of the magnetoresistive element MRD but also the side surface of the pin layer MPL is exposed from the wiring groove TR.

The silicon nitride film in contact with the lower side surface of the magnetoresistive element MRD is left as the silicon nitride film III1 (lower insulating layer III1).

Here, a case is shown where the wiring groove TRa is etched so that the bottom surface of the wiring groove TR is located upper than the uppermost surface of the silicon nitride film III1 over the lower electrode LEL (so that the silicon oxide film II3 is left between the wiring groove TR and the silicon nitride film III1).

For example, when the bottom surface of the wiring groove TR is located lower than the uppermost surface of the silicon nitride film III1 over the lower electrode LEL, the structure is such that a part of a silicon nitride film III1c over the lower electrode LEL is etched and the bottom surface of the bit line BL shown in FIG. 8 and FIG. 9 contacts the lower insulating layer III1.

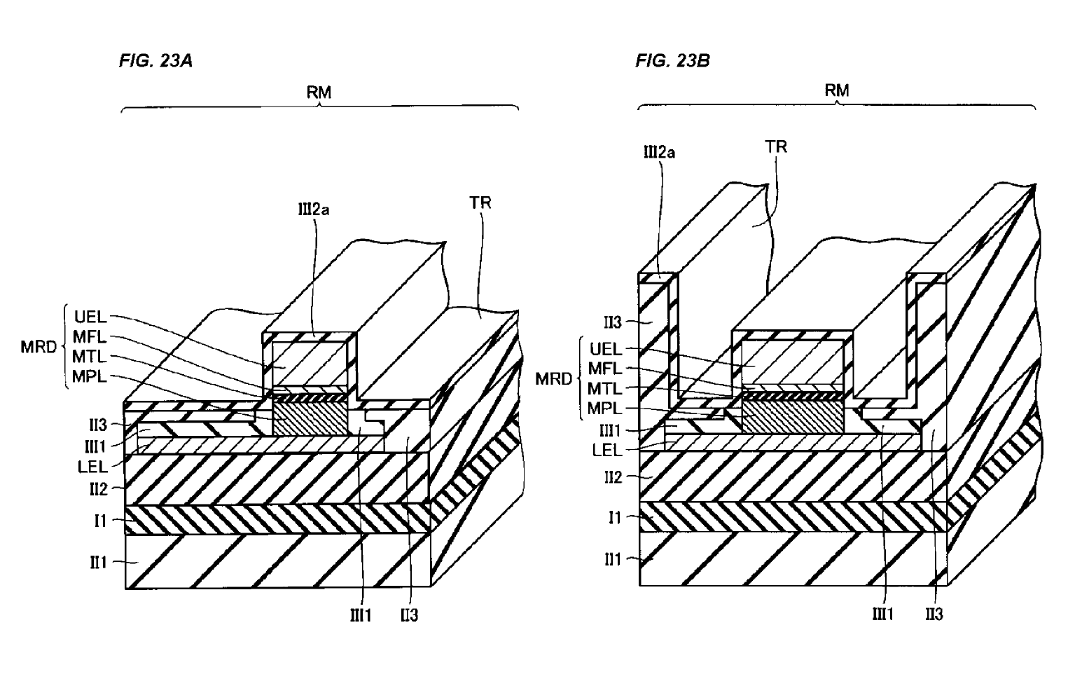

Referring to FIGS. 23(A) and 23(B), a silicon nitride film III2a (second insulating layer) is formed so as to cover the wall surface of the wiring groove TR and the top surface of the interlayer insulating layer II3. The silicon nitride film II12a is formed so as to also cover the top surface and the upper side surface of the magnetoresistive element MRD exposed inside the wiring groove TR. The second insulating layer II12a formed here may be, for example, a silicon oxide film, silicon oxynitride film (SiON), silicon oxycarbide film (SiOC), magnesium oxide (MgO), aluminum oxide (AlO), silicon carbonitride film (SiCN), a silicon carbide (SiC), instead of the silicon nitride film.

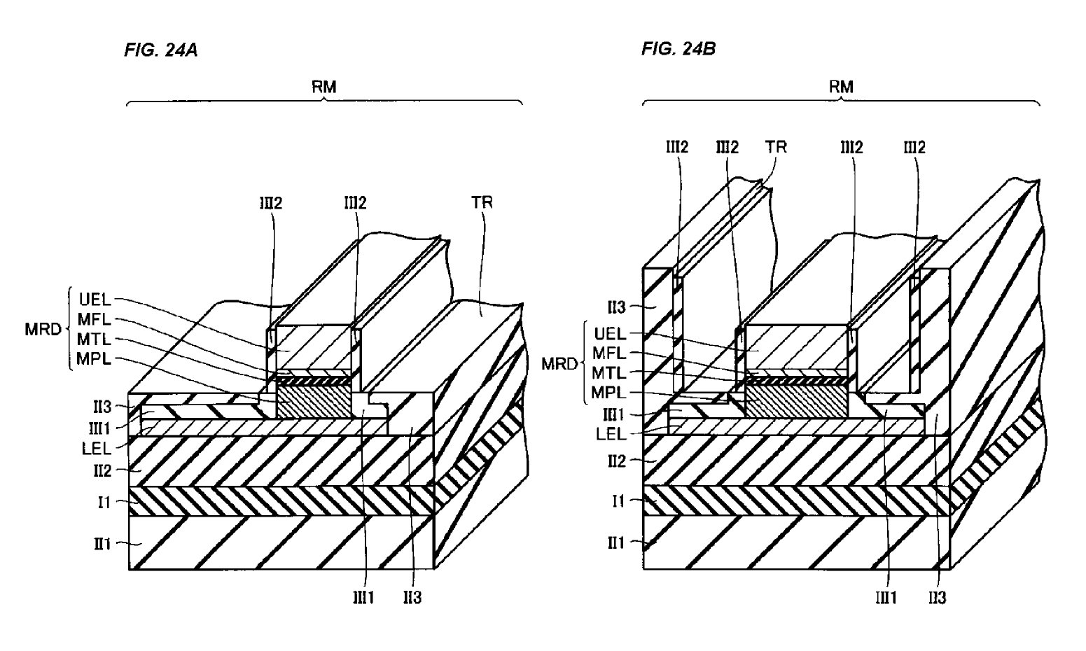

Referring to FIGS. 24 (A) and 24(B), the silicon nitride film III2a is removed by etching until the top surface of the magnetoresistive element MRD is exposed. As a result of that, the silicon nitride film III2a is left on the side surface of the wiring groove TR and the upper side surface of the magnetoresistive element MRD. The silicon nitride film that is left and covers the upper side surface of the magnetoresistive element MRD forms the sidewall insulating layer III2 and the silicon nitride film that covers the side surface of the wiring groove TR forms the silicon nitride film III2. Here, preferably, the sidewall insulating layer III2 is formed so as to contact the top of the side surface somewhat lower than the top surface of the magnetoresistive element MRD.

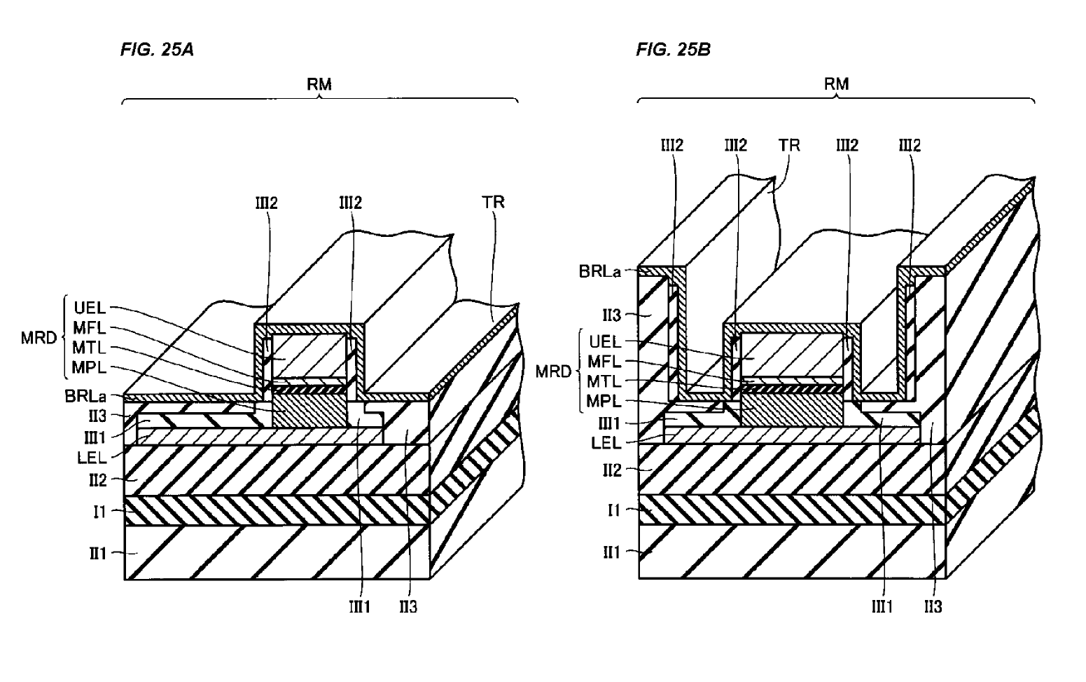

Referring to FIGS. 25(A) and 25(B), the barrier metal BRLa is formed on the top surface of the interlayer insulating layer II3 so as to cover the side surface and the bottom surface of the wiring groove TR. Due to this, over the silicon nitride film III2 and the sidewall insulating layer III2 and over the top surface of the magnetoresistive element MRD are covered with the barrier metal BRLa.

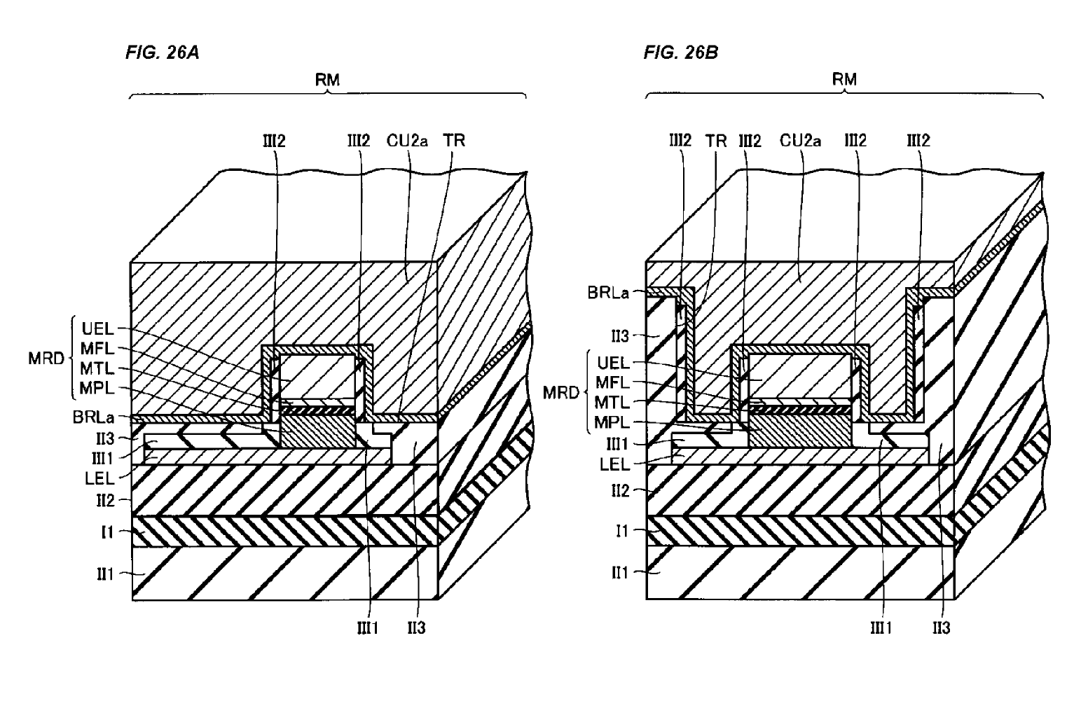

Referring to FIGS. 26(A) and 26(B), a copper film CU2a is formed over the interlayer insulating layer II3 so as to fill in the inside of the wiring groove TR. After this, the copper film CU2a and the silicon oxide film. II3 are subjected to chemical mechanical polishing processing until the top surface of the interlayer insulating layer II3 is exposed.

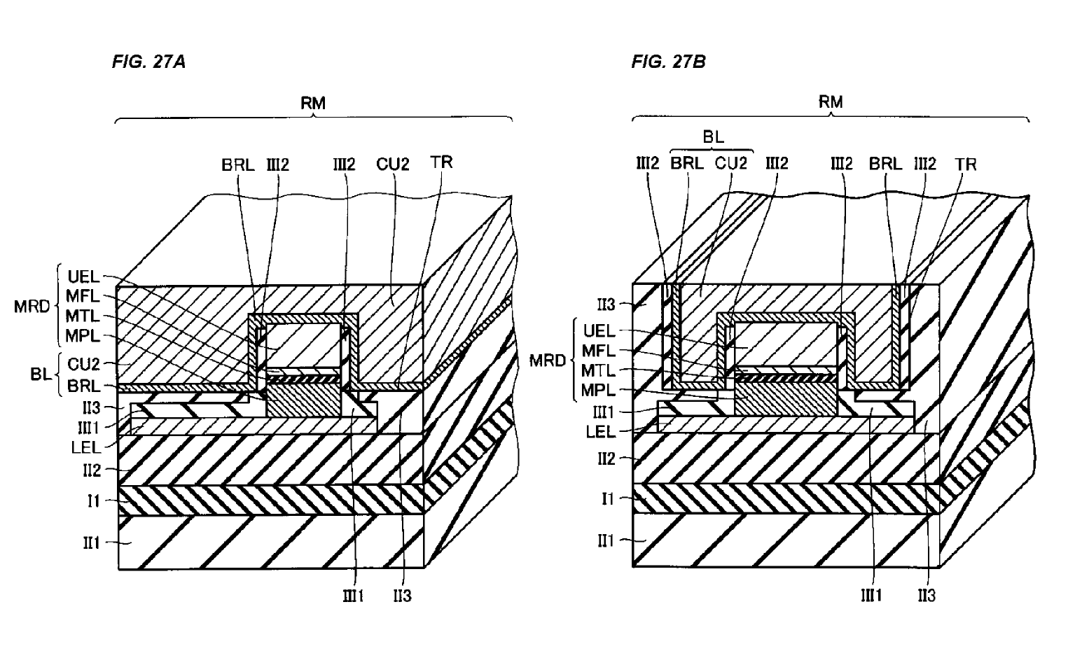

Referring to FIGS. 27(A) and 27(B), by the above-mentioned chemical mechanical polishing processing, the copper film. CU2 and the barrier metal BRL are left within the wiring groove TR and the bit line BL (conductive layer) including the copper film CU2 and the barrier metal BRL is formed. The bit line BL is arranged so as to contact the top surface of the magnetoresistive element MRD, and therefore, the magnetoresistive element MRD and the bit line BL are electrically coupled. The state is brought about where the silicon nitride film III2 is arranged on the side surface of the wiring groove TR and the magnetoresistive element MRD. Further, the silicon oxide film II3 forms the silicon oxide film II3 having a desired thickness.

After this, by further forming a layer over the bit line BL, the STT-MRAM in the present embodiment shown in FIG. 3 to FIG. 7 is formed.

Next, the working and effect of the present embodiment are explained. According to the present embodiment, the side surface of the magnetoresistive element MRD including the pin layer MPL, the tunnel insulating layer MTL, and the free layer MFL is covered with the lower insulating layer III1 and the sidewall insulating layer III2, which are insulating films. Because these protection layers III1, III2 are formed, even if the lower insulating layer III1 covers only a part of the sidewall of the pin layer MPL and both the remaining side surface of the pin layer MPL and the free layer MFL are exposed from the lower insulating layer III1, it is possible for the sidewall insulating layer III2 to cover at least the remaining side surface of the pin layer MPL. Due to this, both the pin layer MPL and the free layer MFL of the magnetoresistive element MRD are prevented from being exposed from the interlayer insulating layer II3 in the wiring groove TR. Because of this, even if the bit line BL is formed within the wiring groove TR, the pin layer MPL and the free layer MFL are suppressed from being electrically short-circuited by the bit line BL. Because of this, it is possible to suppress the reduction in yields of the MRAM element due to the above-mentioned short circuit.

In the manufacturing method of the present embodiment, after the wiring groove TR is formed, the sidewall insulating layer III2 (the silicon oxide film III2a) is formed so as to cover the upper side surface of the magnetoresistive element MRD. Because of this, even if the relative relationship in the longitudinal direction (vertical direction) between the bottom part of the wiring groove TR and the magnetoresistive element MRD varies in the wafer plane, the bit line BL is prevented from contacting both the pin layer MPL and the free layer MFL by the sidewall insulating layer III2. Because of this, the margin of the depth of the wiring groove TR to form the bit line BL is increased, and therefore, the control of the depth of the wiring groove TR is made easier.

### Second Embodiment

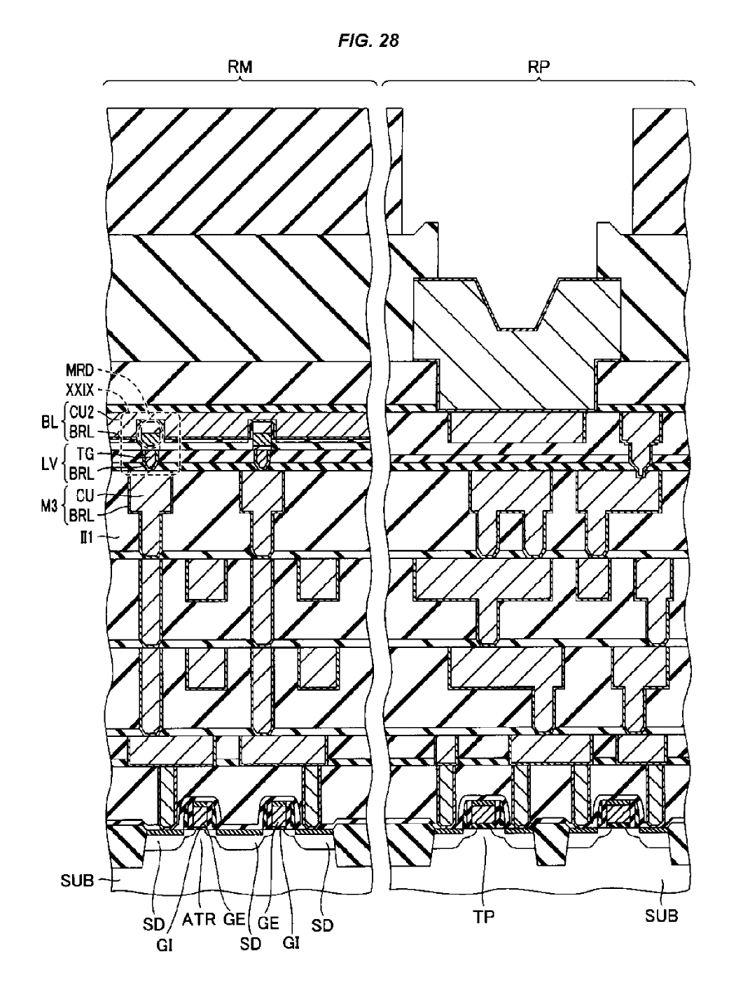

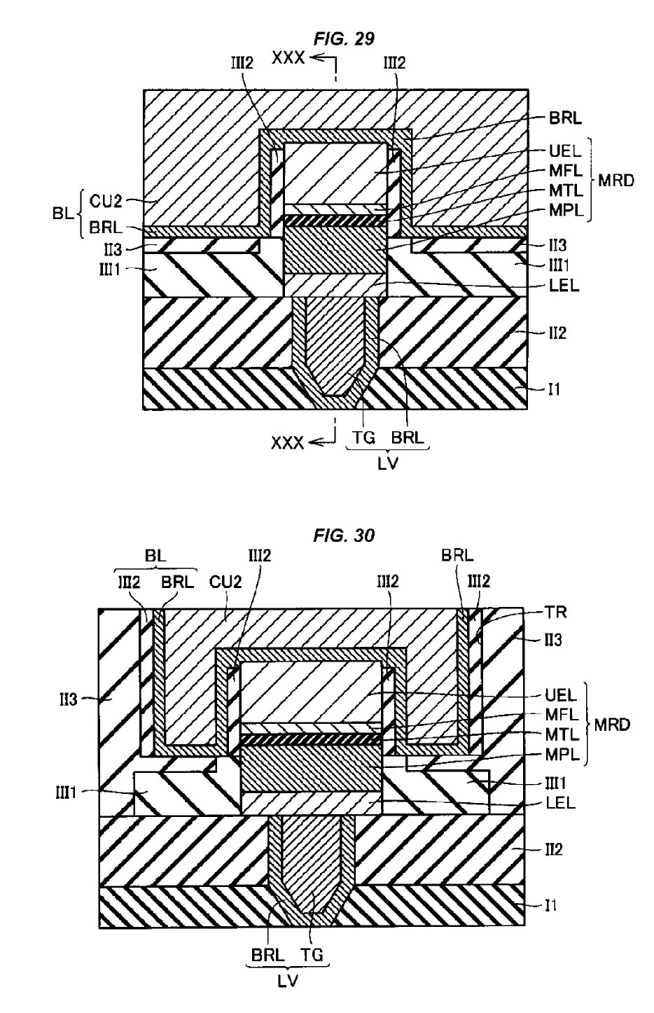

In a second embodiment of the present invention, the structure of the lower electrode LEL and the manufacturing method thereof are different compared to those in the first embodiment. The structure of the present embodiment is explained below using FIG. 28 to FIG. 30.

Referring to FIG. 28 to FIG. 30, the memory cell of the STT-MRAM formed in the memory cell region RM of the present embodiment is arranged only in a region where the lower electrode LEL substantially overlaps the magnetoresistive element MRD in a planar view. In other words, the lower electrode LEL is arranged substantially only right below the magnetoresistive element MRD. Consequently, the size of the lower electrode LEL in a planar view is substantially the same as the size of the magnetoresistive element MRD in a planar view or a somewhat smaller size. Because the lower electrode LEL is arranged only right below the magnetoresistive element MRD, the local via LV is similarly arranged only in a position where it substantially overlaps the magnetoresistive element MRD in a planar view.

The structure in the present embodiment shown in FIG. 28 to FIG. 30 differs from that in the first embodiment shown in FIG. 5 to FIG. 7 in the above points and other points are the same as those of the configuration in the first embodiment shown in FIG. 5 to FIG. 7, and therefore, the same symbol is attached to the same component and its explanation is not repeated.

The manufacturing method of the STT-MRAM in the present embodiment is almost the same as that of the STT-MRAM in the first embodiment. However, it is formed so that all of the read wiring M3, the local via LV, the lower electrode LEL, and the magnetoresistive element MRD substantially overlap one another in a planar view (so that all of them have substantially the same size in a planar view).

Because of this, in the manufacturing method of the present embodiment, for example, in the step shown in FIG. 17 of the first embodiment, the lower electrode LELa is etched so as to have substantially the same size as that of the pin layer MPL, the free layer MFL, etc. Further, in the step, the pin layer MPL, the free layer MFL, etc., are formed in substantially the same position of the local via LV, the lower electrode LEL in a planar view.

Next, the working and effect of the present embodiment are explained. The present embodiment has the following effect besides the working and effect of the first embodiment.

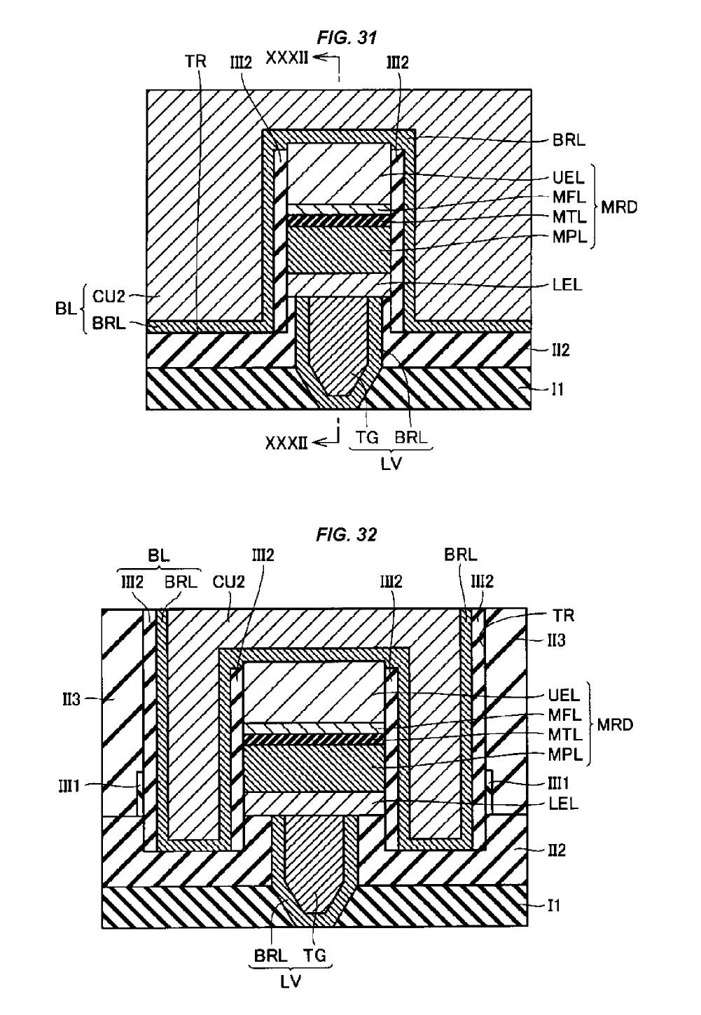

In the present embodiment also, there is a case where the wiring groove TR is formed deeper due to the variations in the depth of the wiring groove TR to form the bit line BL as shown in FIG. 32 and FIG. 32 as in the first embodiment shown in FIG. 8 and FIG. 9.

Referring to FIG. 31 and FIG. 32, in this case, there is a case where the bottom surface of the wiring groove TR reaches a part lower than the lower electrode LEL at the bottom part (region where the magnetoresistive element MRD is not arranged in a planar view) of the wiring groove TR. In this case, the entire lower insulating layer III1 is etched at the bottom part of the wiring groove TR and the bottom part of the wiring groove TR (bottom part of the bit line BL) contacts the interlayer insulating layer II2. Further, in this case, only the sidewall insulating layer III2 contacts each side surface of the magnetoresistive element MRD and the lower electrode LEL. Because the sidewall insulating layer III2 covers the upper and lower side surfaces of the magnetoresistive element MRD and the side surface of the lower electrode LEL, the short circuit between the pin layer MPL and the free layer MFL is suppressed as in the first embodiment.

For example, in the case of the first embodiment, if the bottom surface of the wiring groove TR contacts the lower electrode LEL, the wiring groove TR and the lower electrode LEL short circuit. However, in the present embodiment, on the undersurface of the wiring groove TR, the lower electrode LEL is not arranged except for the region in which the magnetoresistive element MRD is formed in a planar view. Because of this, the bottom surface of the wiring groove TR is unlikely to short circuit with the lower electrode LEL as shown in FIG. 31 and FIG. 32. Because of this, it is possible to suppress the short circuit of the bit line BL more securely than in the first embodiment.

The structure in FIG. 31 and FIG. 32 differs from that in FIG. 8 and FIG. 9 in the points described above and other points are the same as those in FIG. 8 and FIG. 9, and therefore, the same symbol is attached to the same component and its explanation is not repeated.

The second embodiment of the present invention differs from the first embodiment of the present invention only in each point described above. That is, the structures, conditions, procedures, effects, etc., not described in the second embodiment of the present invention are all the same as those in the first embodiment of the present invention.

### Third Embodiment

A third embodiment of the present invention differs from the first embodiment in the configuration of the wiring coupled to the upper side of the magnetoresistive element MRD and the manufacturing method. The configuration of the present embodiment is explained below using FIG. 33 to FIG. 35.

While in the first embodiment shown in FIG. 5 to FIG. 7, the bit line BL has the configuration to fill in the inside of the wiring groove TR provided on the top surface of the interlayer insulating layer II3, the bit line BL in the present embodiment shown in FIG. 33 to FIG. 35 has a configuration in which an aluminum thin film is patterned over the top surface of the interlayer insulating layer II3. That is, while the bit line BL in the first embodiment shown in FIG. 5 to FIG. 7 is located lower than the top surface of the interlayer insulating layer II3, the bit line BL in the present embodiment shown in FIG. 33 to FIG. 35 is located upper than the top surface of the interlayer insulating layer II3.

The structure in the present embodiment shown in FIGS. 33 to 35 differs from that in the first embodiment shown in FIG. 5 to FIG. 7 in the points described above and other points are the same as those of the structure in the first embodiment shown in FIG. 5 to FIG. 7, and therefore, the same symbol is attached to the same component and its explanation is not repeated.

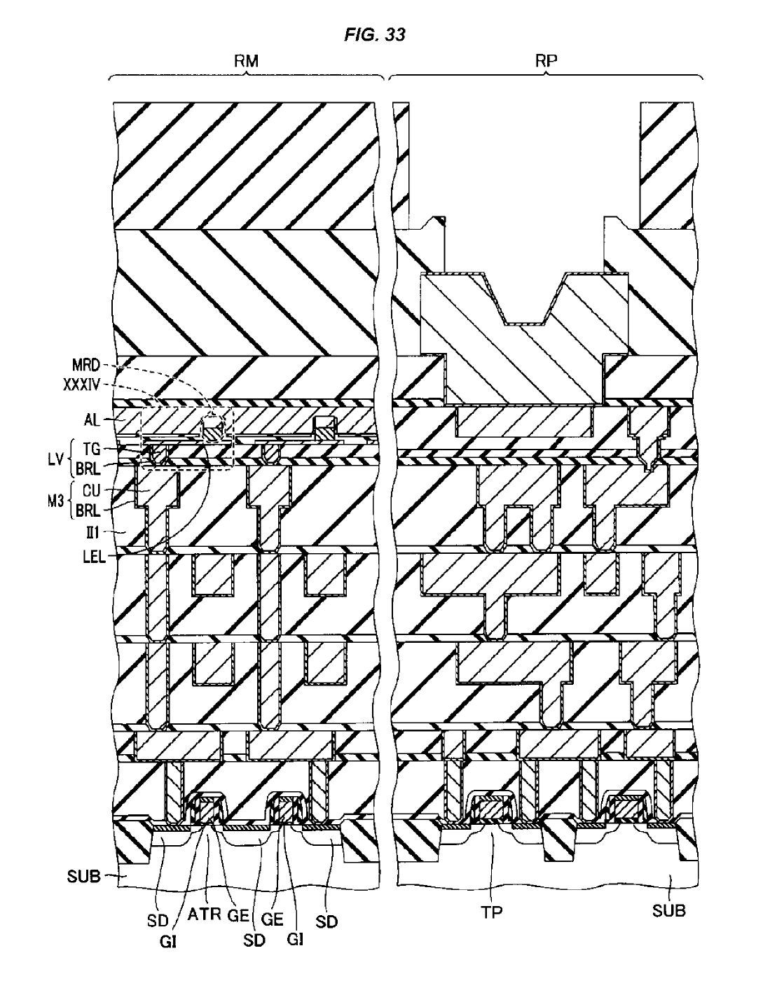

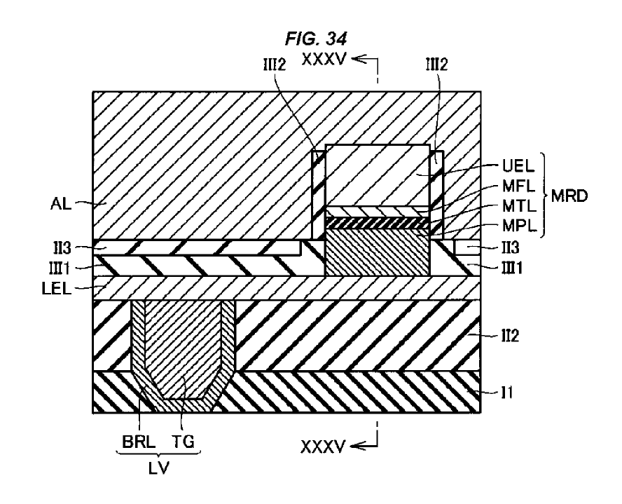

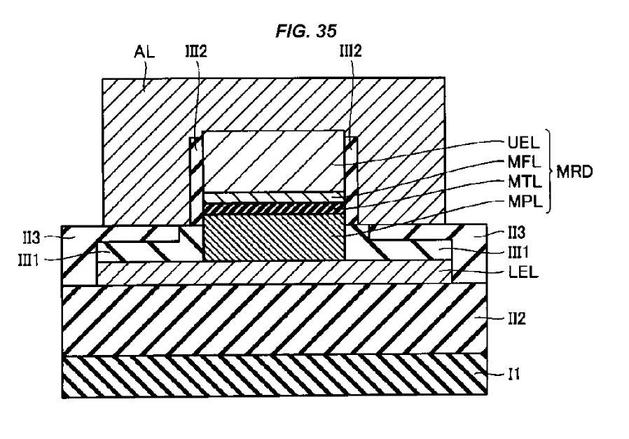

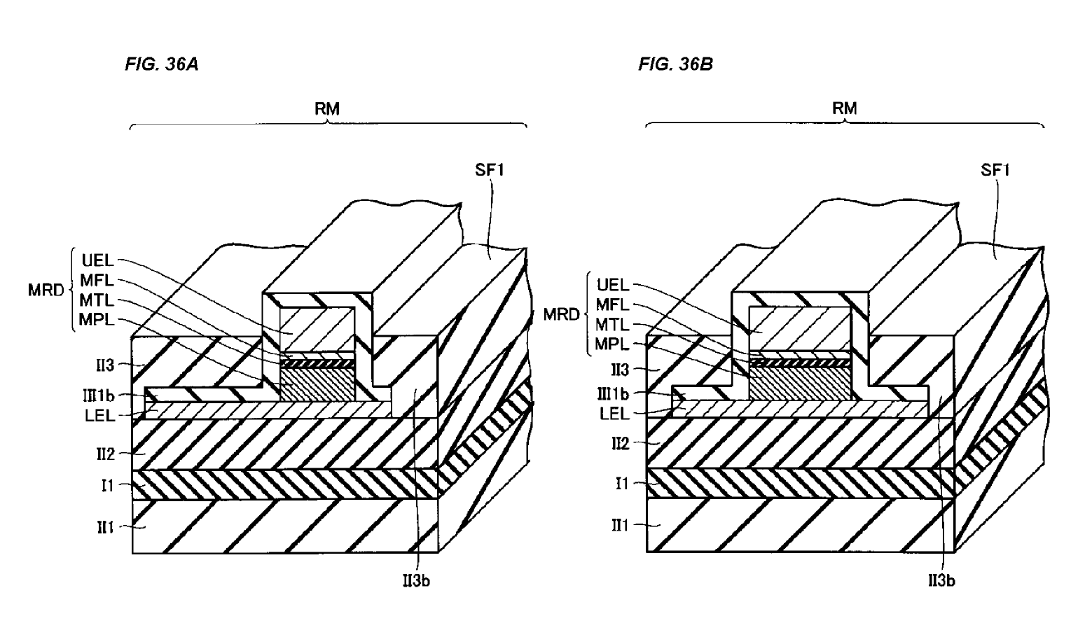

Next, the manufacturing method of the STT-MRAM shown in FIG. 33 to FIG. 35 as a semiconductor in the present embodiment is explained using FIG. 36 to FIG. 40. The following FIG. 36 to FIG. 40 show sectional views (A) when viewed in the same direction as that in FIG. 13 to FIG. 20 and sectional views (B) (sectional view along the XXI-XXI line in FIG. 20) when the magnetoresistive element MRD is cut in the direction perpendicular to that in FIG. 13 to FIG. 20.

Referring to FIGS. 36(A) and 36(B), after the step shown in FIG. 20, by the etching technique, the entire surface of the top surface of the interlayer insulating layer II3 including a silicon oxide film is removed by an amount corresponding to a desired thickness. Due to this, from the interlayer insulating layer II3, the surface of the silicon nitride film III1b that covers the top surface and the side surface of the magnetoresistive element MRD is exposed. A part of the silicon nitride film III1b exposed from the interlayer insulating layer II3 is removed by etching.

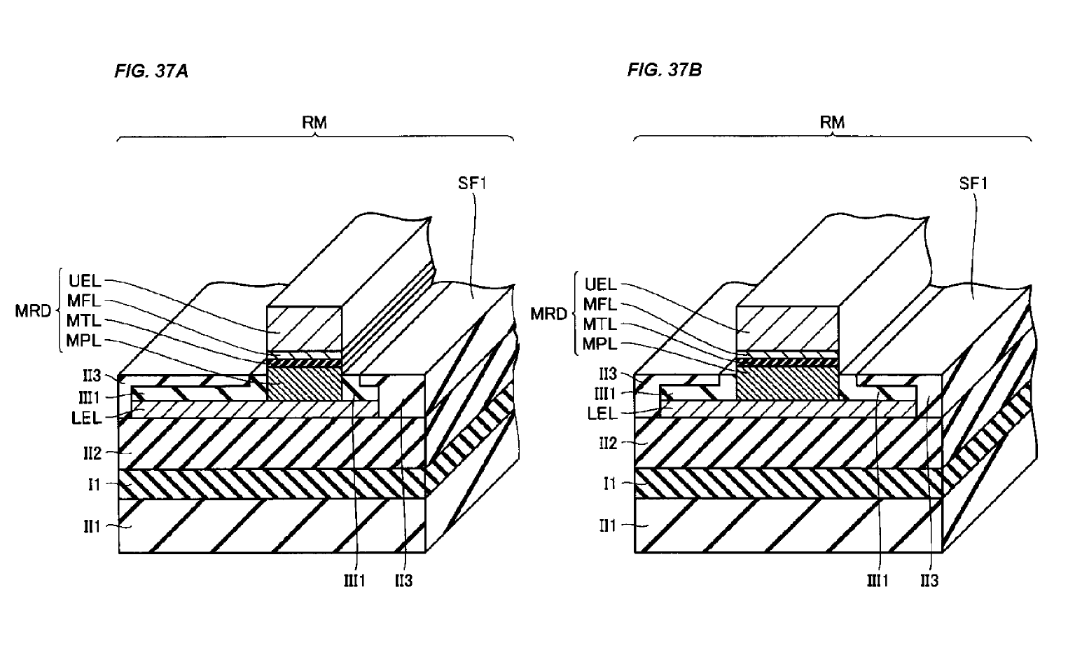

Referring to FIGS. 37(A) and 37(B), by the above-mentioned etching, the part of the silicon nitride film III1b exposed from the interlayer insulating layer II3 is removed by etching and the upper side surface and the top surface of the magnetoresistive element MRD are exposed. By this etching, the part in contact with the lower side surface of the magnetoresistive element MRD and the part extending over the lower electrode LEL of the silicon nitride film III1b are left to form the lower insulating layer III1. At the time of the etching, the top surface of the interlayer insulating layer II3 is scraped and the interlayer insulating layer II3 becomes further thinner. At this time, there is a case where not only the side surface of the free layer MFL and the tunnel insulating layer MTL of the magnetoresistive element MRD but also the side surface of the pin layer MPL is exposed from the interlayer insulating layer II3 due to the variations in each step.

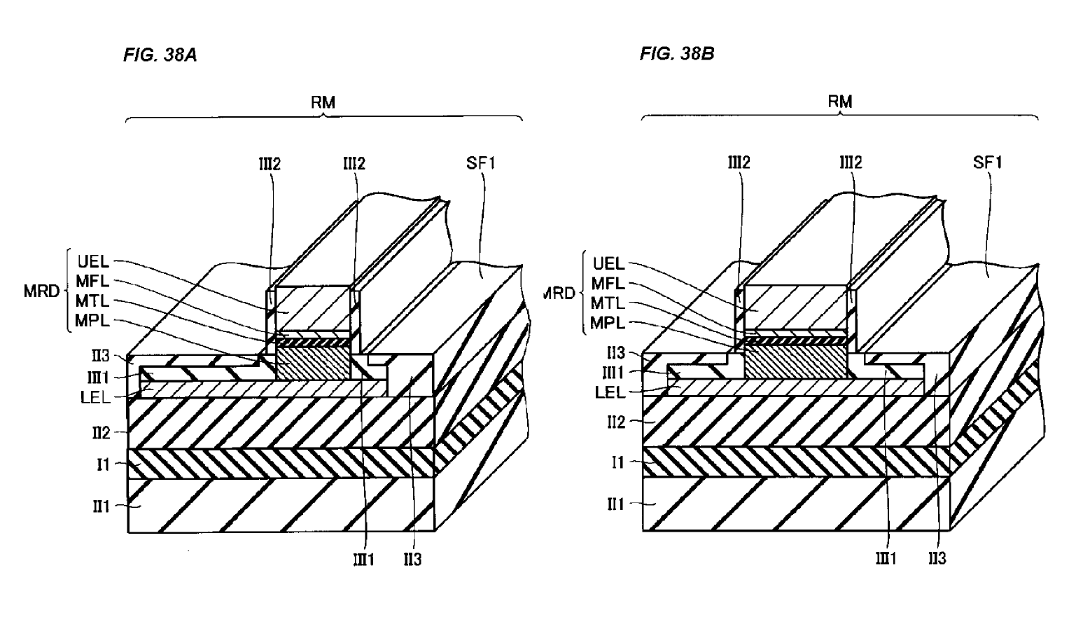

Referring to FIGS. 38(A) and 38(B), the silicon nitride film III2 is formed so as to cover a top surface SF1 of the interlayer insulating layer II3. The silicon nitride film III2 is formed so as to also cover the top surface and the upper side surface of the magnetoresistive element MRD exposed from the interlayer insulating layer II3. After that, the silicon nitride film III2 is etched. Due to this, the silicon nitride film III2 is left to cover the upper side surface of the magnetoresistive element MRD as well as exposing the top surface of the magnetoresistive element MRD.

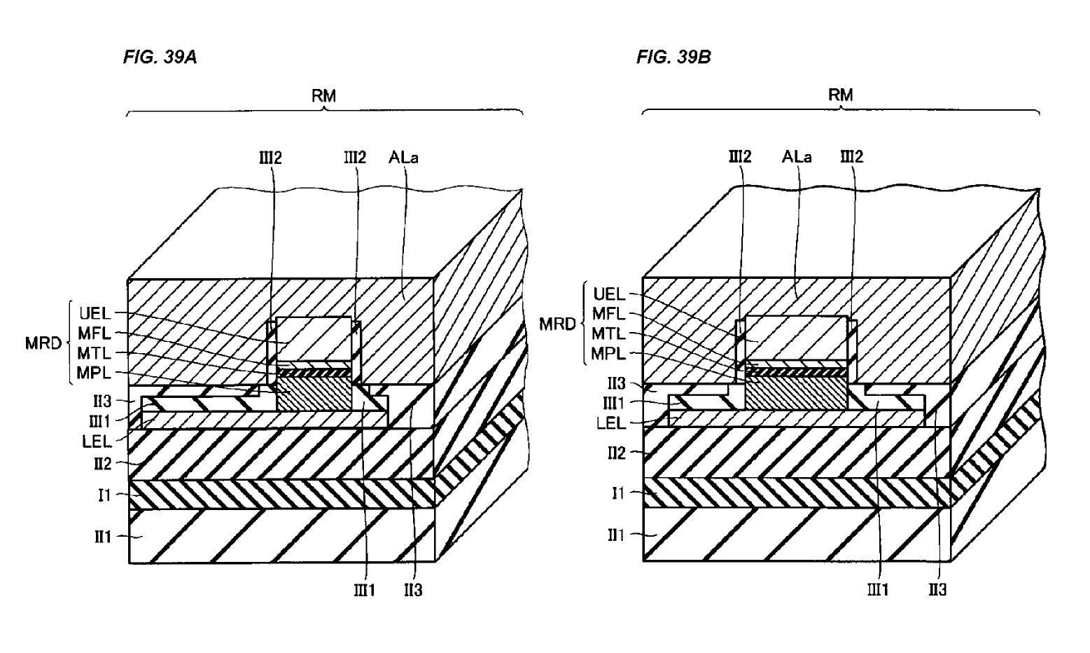

Referring to FIGS. 39(A) and 39(B), an aluminum thin film ALa is formed so as to cover the top surface and side surface of the magnetoresistive element MRD and the entire surface of the top surface SF1 of the interlayer insulating layer II3. The aluminum thin film ALa is a thin film made of a conductive material to form a conductive layer.

Here, the aluminum thin film ALa is formed so as to be sufficiently thick to embed the magnetoresistive element MRD exposed from the interlayer insulating layer II3.

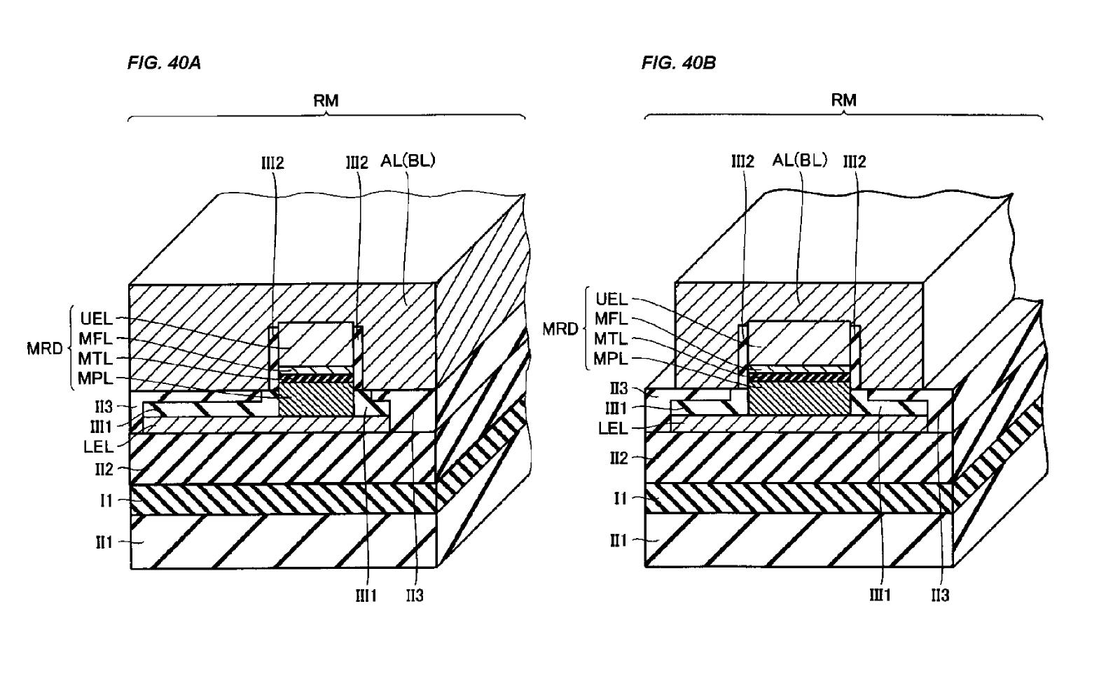

Referring to FIGS. 40(A) and 40(B), by the normal photoengraving technique and etching, the aluminum thin film ALa is selectively removed and patterned so as to be left only in the desired region. Due to this processing, the bit line BL including a patterned aluminum wiring AL is formed.

After this, by further forming a layer over the aluminum wiring AL, the STT-MRAM in the present embodiment shown in FIG. 33 to FIG. 35 is formed.

In the STT-MRAM also, in which the aluminum wiring Al is arranged as the bit line BL as in the present embodiment, the same effect as that of the STT-MRAM in the first embodiment is achieved.

The structure of the present embodiment may be combined with that of the second embodiment. The third embodiment of the present invention differs from the first embodiment of the present invention only in each point described above. That is, all of the structures, conditions, procedures, effects, etc., not described in the third embodiment of the present invention are the same as those in the first embodiment of the present invention.

### Fourth Embodiment

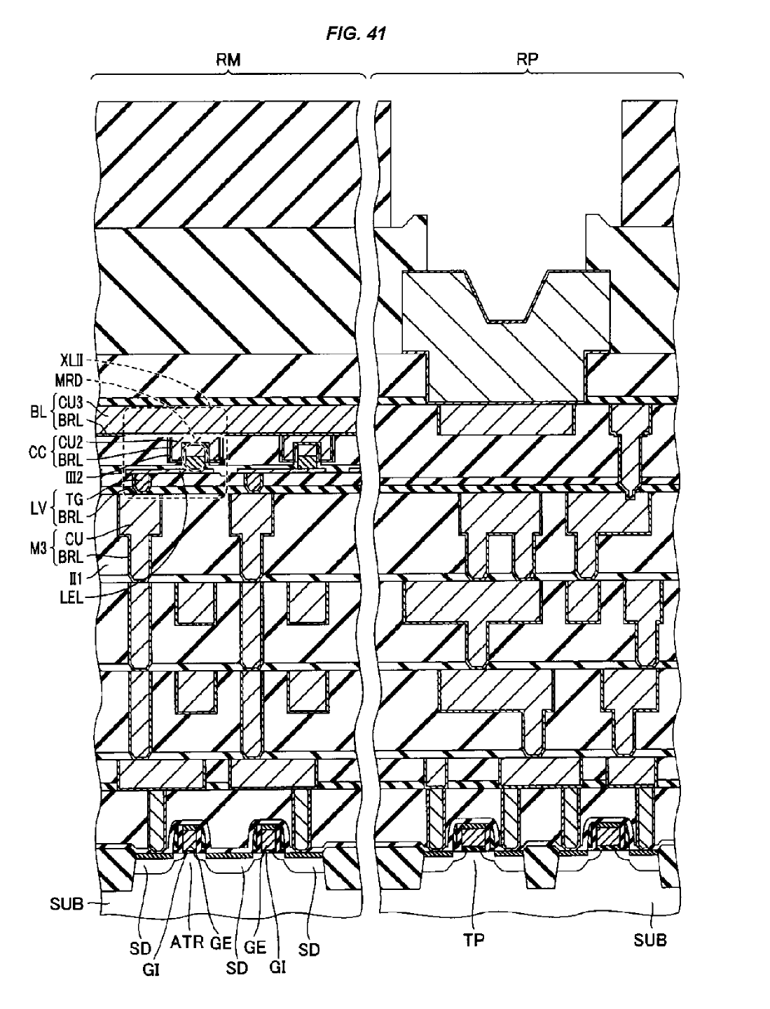

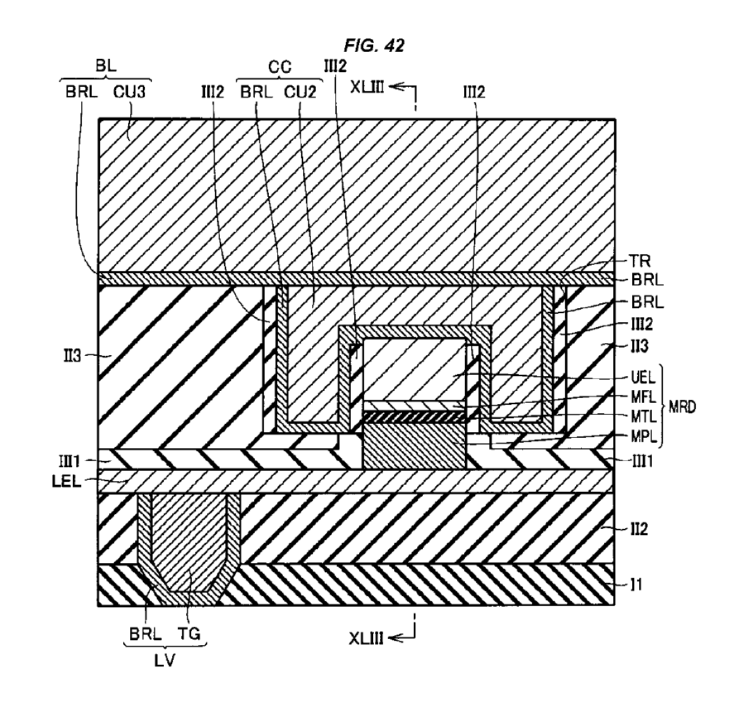

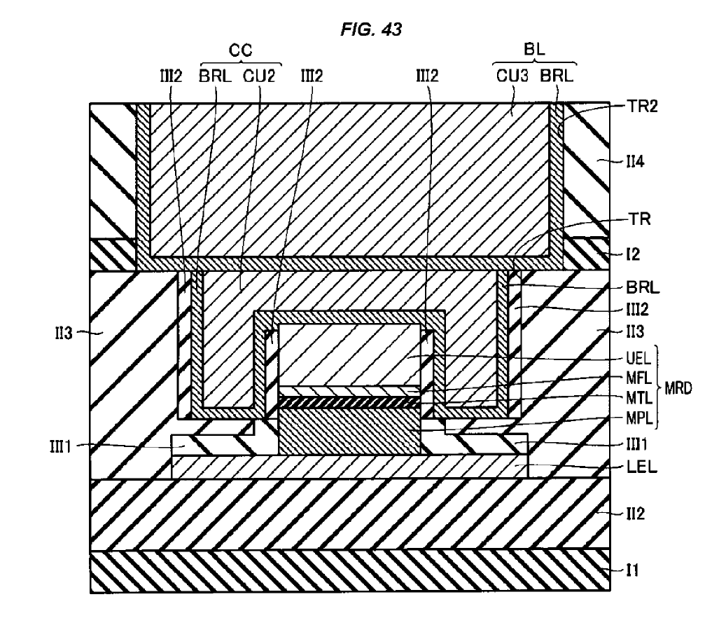

A fourth embodiment differs from the first embodiment in that the magnetoresistive element MRD is electrically coupled to a bit line via a coupling conductive layer. The structure of the present embodiment is explained below using FIG. 41 to FIG. 43.

Referring to FIG. 41 to FIG. 43, in a memory cell of an STT-MRAM formed in the memory cell region RM of the present embodiment, a coupling conductive layer CC is formed so as to be electrically coupled to the upper side of the magnetoresistive element MRD and the bit line BL is formed over the coupling conductive layer CC so as to be electrically coupled to the magnetoresistive element MRD via the coupling conductive layer CC.

The coupling conductive layer CC is formed within the via groove TR (coupling groove) provided on the top surface of the interlayer insulating layer II3 and has the barrier metal BRL and the copper film CU2 that forms the conductive layer main body. The barrier metal BRL is formed along the inner wall surface of the via groove TR and preferably includes a thin film including, for example, Ta (tantalum) etc. The copper film CU2 is formed so as to fill in the inside of the via groove TR.

The coupling conductive layer CC is in contact with the top surface and a part of the upper side surface of the magnetoresistive element MRD exposed from the sidewall insulating layer III2. The coupling conductive layer CC is not configured to extend in the direction along the main surface of the semiconductor substrate SUB like the bit line BL in the first embodiment. On the sidewall surface of the via groove TR, the sidewall insulating layer III2 is formed as in the first embodiment.

Over the top surface of the interlayer insulating layer II3, the bit line BL is formed and the bit line BL has the barrier metal BRL and the copper film CU2 that forms the wiring main body. The bit line BL is in contact with the top surface of the coupling conductive layer CC and due to that, is electrically coupled to the magnetoresistive element MRD via the coupling conductive layer CC. As in the first embodiment, the bit line BL is configured to extend in one direction along the main surface of the semiconductor substrate SUB.

The structure of the present embodiment shown in FIG. 41 to FIG. 43 differs from that of the first embodiment shown in FIG. 5 to FIG. 7 in the points described above and other points are the same as those of the structure of the first embodiment shown in FIG. 5 to FIG. 7, and therefore, the same symbol is attached to the same component and its explanation is not repeated.

Next, a manufacturing method of the STT-MRAM shown in FIG. 41 to FIG. 43 as a semiconductor device of the present embodiment is explained using FIG. 44 to FIG. 51. The following FIG. 44 to FIG. 51 show sectional views (A) when viewed in the same direction as that in FIG. 13 to FIG. 20 and sectional views (B) (sectional view along the XXI-XXI line in FIG. 20) when the magnetoresistive element MRD is cut in the direction perpendicular to that in FIG. 13 to FIG. 20.

Referring to FIGS. 44(A) and 44(B), after the step shown in FIG. 20, by the photoengraving technique and etching technique, the via groove TRa is formed in the interlayer insulating layer II3 including a silicon oxide film. The via groove TRa is a groove to internally embed the coupling conductive layer CC. Because of this, the via groove TR does not extend in one direction along the main surface of the semiconductor substrate SUB as, for example, the wiring groove TRa in FIG. 21, but is formed only around the magnetoresistive element MRD in a planar view. However, from the via groove TRa in FIG. 44, the surface of the silicon nitride film III1b that covers the top surface and the side surface of the magnetoresistive element MRD is exposed as the wiring groove TRa in FIG. 21

After this, the silicon nitride film III1b that is exposed from the interlayer insulating layer II3 is removed by etching.

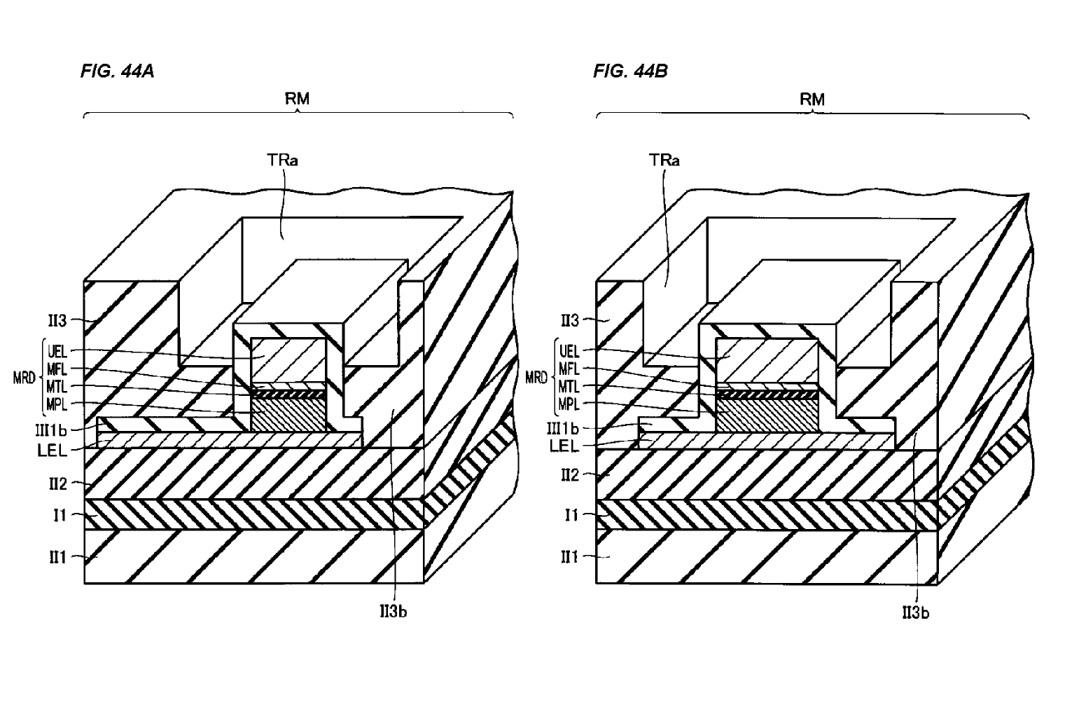

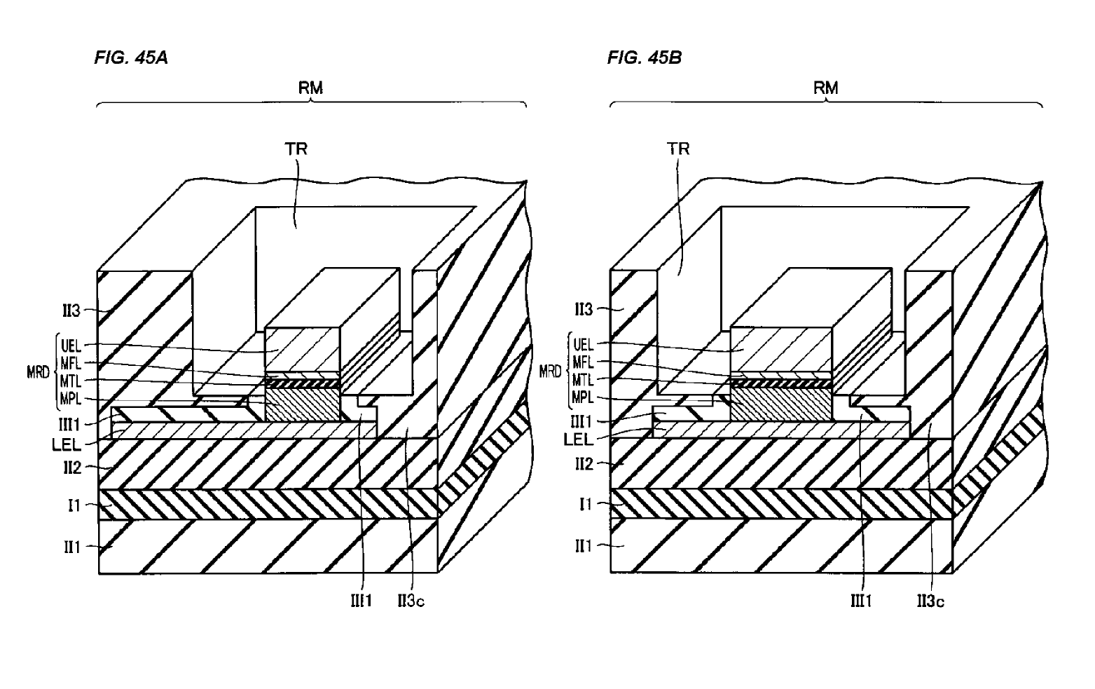

Referring to FIGS. 45(A) and 45(B), as in FIG. 22, by the etching, the part of the silicon nitride film III1b which is exposed from the via groove TRa is removed and the upper side surface and the top surface of the magnetoresistive element MRD are exposed. At the time of the etching, the bottom part of the via groove TRa is scraped by the etching and the via groove TRa becomes deeper and forms the via groove TR. The silicon nitride film in contact with the lower side surface of the magnetoresistive element MRD is left as the silicon nitride film III1 (lower insulating layer III1).

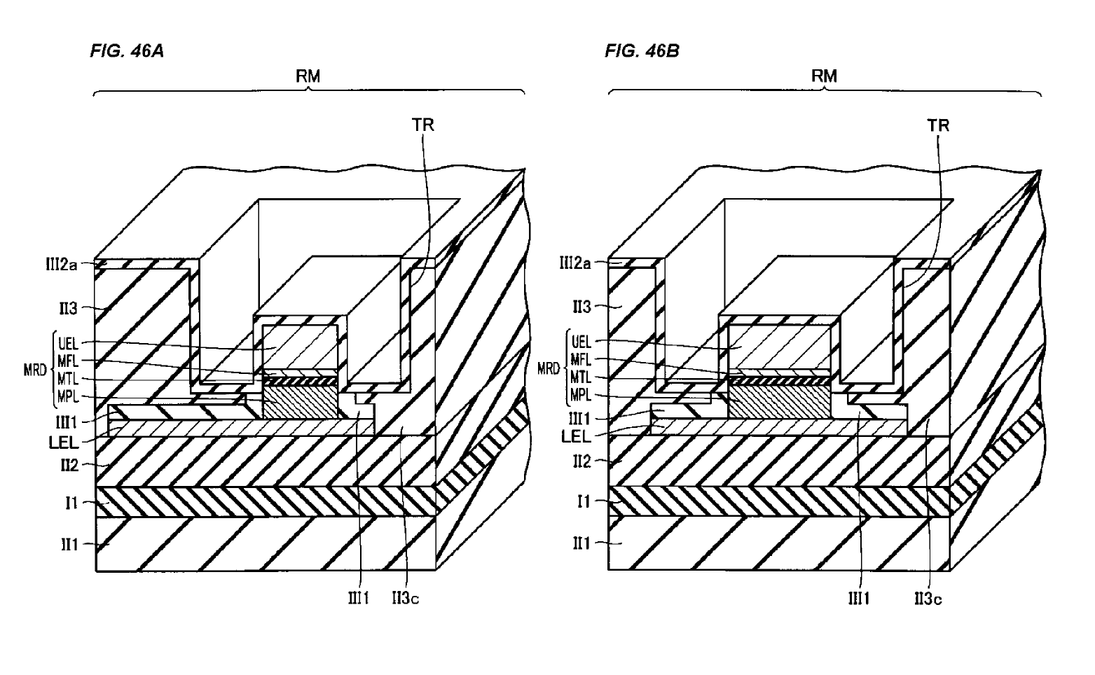

Referring to FIGS. 46(A) and 46(B), as in FIG. 23, the silicon nitride film II12a is formed so as to cover the wall surface of the via groove TR and the top surface of the interlayer insulating layer II3. The silicon nitride film III2a is formed so as to also cover the top surface and the upper side surface of the magnetoresistive element MRD exposed inside the via groove TR. After this, as in FIG. 24, the silicon nitride film III2a is removed by etching so that the top surface of the magnetoresistive element MRD is exposed.

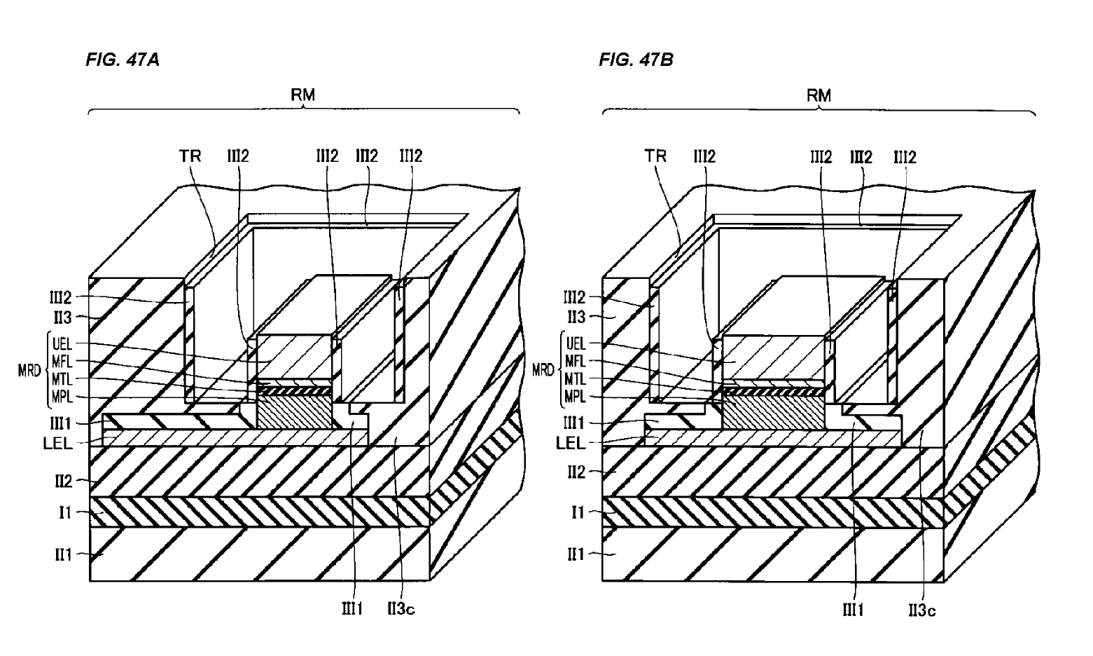

Referring to FIGS. 47(A) and 47(B), by the etching, the silicon nitride film III2a is left on the side surface of the via groove TR and at the same time, the sidewall insulating layer III2 is left on the upper side surface of the magnetoresistive element MRD.

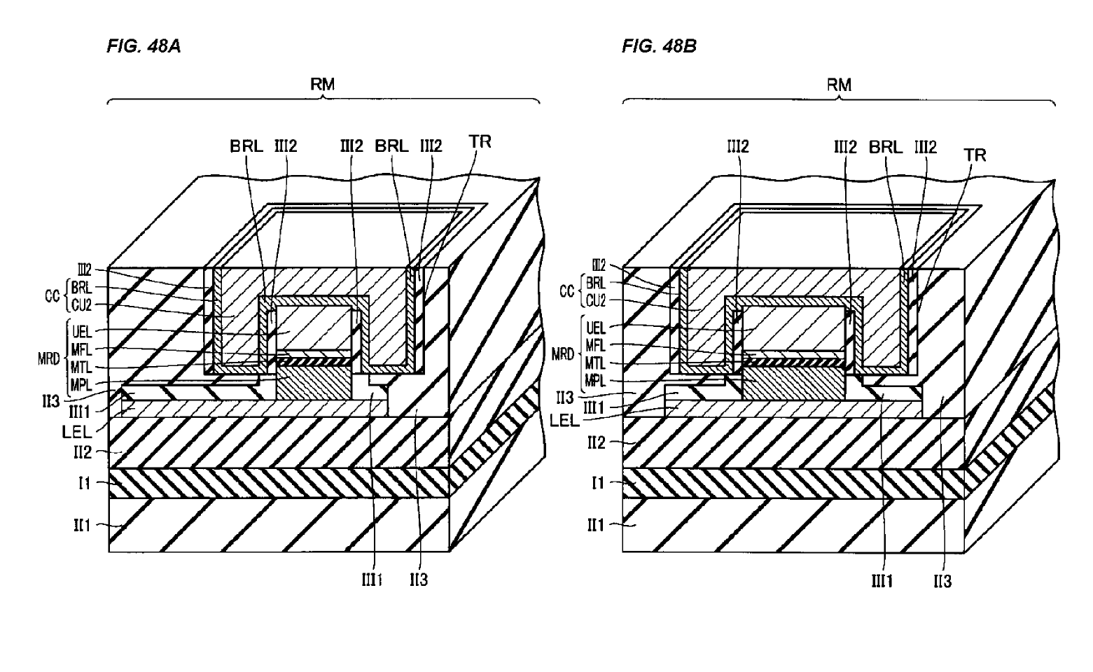

Referring to FIGS. 48(A) and 48(B), by performing the same processing as that in FIG. 25, FIG. 26, FIG. 27, the copper film CU2, the barrier metal BRL, and the vacant coupling conductive layer CC are formed so as to fill in the inside of the via groove TR.

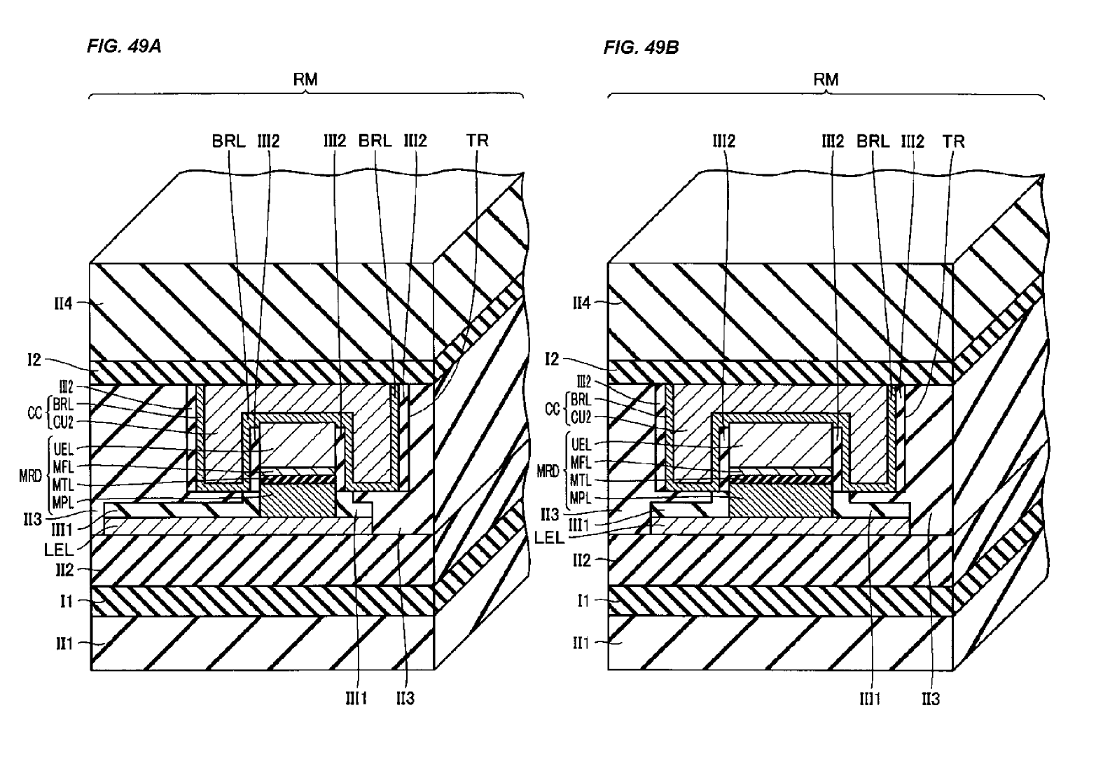

Referring to FIGS. 49(A) and 49(B), the silicon nitride film 12 and the silicon oxide film 114 as an interlayer insulating layer are formed in this order on the top surface of the interlayer insulating layer II3 so as to cover over the coupling conductive layer CC. As an example, the silicon nitride film I2 is formed under the temperature condition of 275° C. so as to have a thickness of 60 nm. The silicon oxide film II4 is formed under the temperature condition of 250° C. so as to have a thickness of 300 nm.

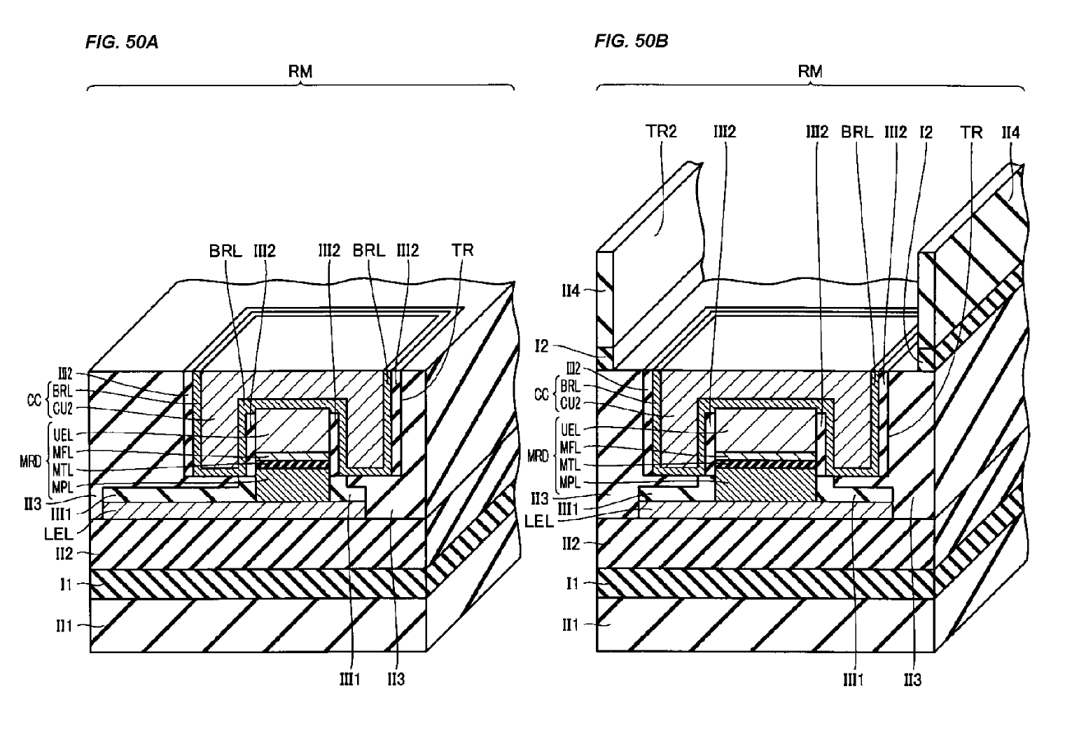

Referring to FIGS. 50(A) and 50(B), by the normal photoengraving technique and the etching technique, a wiring groove TR2 that reaches the top surface of the coupling conductive layer CC is formed in the interlayer insulating layer I2 and an interlayer insulating layer II4. Like the wiring groove TRa in FIG. 21, the wiring groove TR2 is formed so as to extend in one direction along the main surface of the semiconductor substrate SUB and to expose the top surface of the coupling conductive layer CC.

Preferably, the width in the direction (horizontal direction in FIG. 50(B)) crossing the direction in which the wiring groove TR2 extends is greater than the width of the coupling conductive layer CC. As an example, it can be supposed that the width is set to 740 nm.

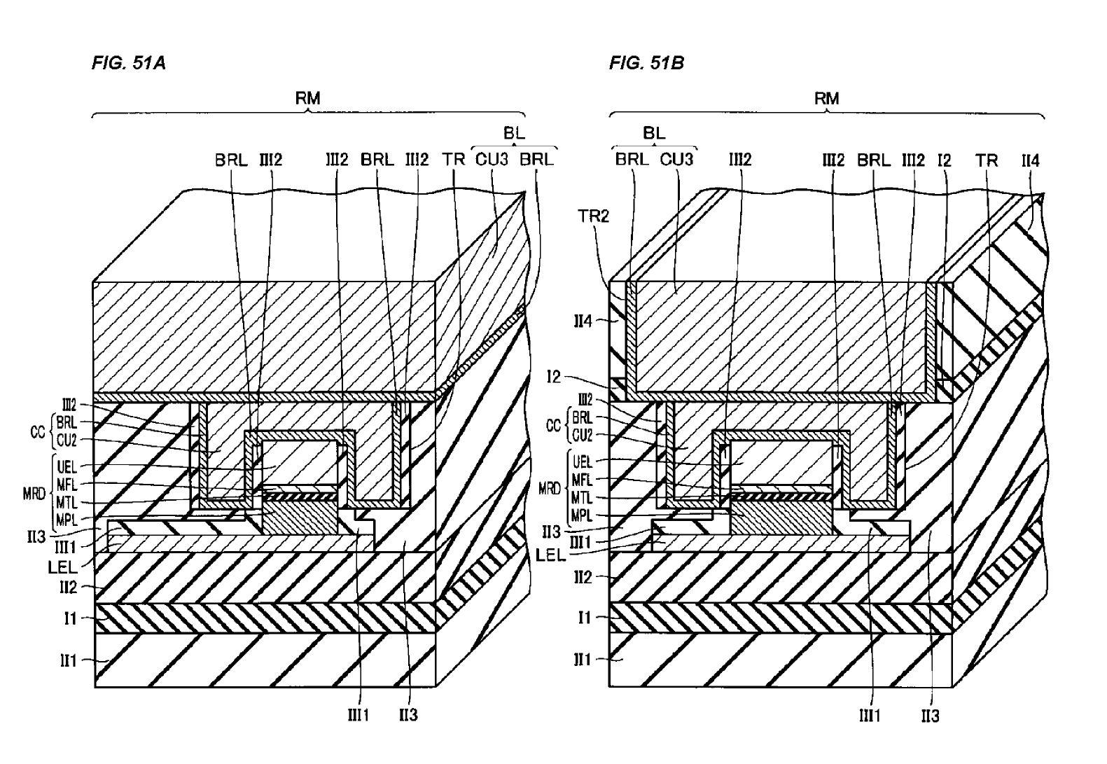

Referring to FIGS. 51(A) and 51(B), first, by the same processing as that in FIG. 25, the barrier metal BRL is formed on the top surface of the interlayer insulating layer 114 so as to cover the side surface and the bottom surface of the wiring groove TR2. Next, by the same processing as that in FIG. 26, a copper film CU3 is formed over the interlayer insulating layers 12, 114 so as to fill in the inside of the wiring groove TR2. After this, the copper film CU3 and the barrier metal BRL are removed by polishing by the chemical mechanical polishing processing until the top surface of the interlayer insulating layer 114 is exposed.

By the chemical mechanical polishing processing, the copper film CU3 and the barrier metal BRL are left within the wiring groove TR2 and the bit line BL (first wiring layer) including the copper film CU3 and the barrier metal BRL is formed. By the above, the structure in which the magnetoresistive element MRD, the coupling conductive layer CC, and the bit line BL are electrically coupled to one another is formed.

Preferably, the thickness of the bit line BL formed here is not less than 200 nm and not more than 400 nm and more preferably, not less than 200 nm and not more than 300 nm. As an example, it can be supposed that the thickness is set to 270 nm.

After this, by further forming a layer over the bit line BL, the STT-MRAM of the present embodiment shown in FIG. 41 to FIG. 43 is formed.

Next, the working and effect of the present embodiment are explained. In the present embodiment, between the magnetoresistive element MRD and the bit line BL, the coupling conductive layer CC (hole) that electrically couples them is arranged and the size of the coupling conductive layer CC in a planar view is larger than that of the magnetoresistive element MRD. In this case also, by the coupling conductive layer CC, the pin layer MPL and the free layer MFL of the magnetoresistive element MRD are prevented from short circuiting. This is because the upper side surface (inside of the coupling conductive layer CC) of the magnetoresistive element MRD is covered with the sidewall insulating layer III2 and the lower side surface of the magnetoresistive element MRD is covered with the lower insulating layer III1.

Because of this, with the structure of the present embodiment, it is possible to suppress the pin layer MPL and the free layer MFL of the magnetoresistive element MRD from short circuiting even if reduction in the plane size of the magnetoresistive element MRD advances and the via groove TR that is electrically coupled to the bit line BL becomes larger than the magnetoresistive element MRD in a planar view. Because of this, it is possible to suppress the reduction in yields of the memory cell element resulting from the miniaturization of the magnetoresistive element MRD.

According to the manufacturing method of the present embodiment, even if the relative relationship between the bottom part of the via groove TR and the magnetoresistive element MRD in the longitudinal direction (vertical direction) varies in the wafer plane when the via groove TR is formed, the coupling conductive layer CC is prevented from contacting both the pin layer MPL and the free layer MFL by the sidewall insulating layer III2. Because of this, the margin of the depth of the via groove TR becomes large and it is made easier to control the depth of the via groove TR.

It may also be possible to combine the structure of the present embodiment with that of the second embodiment or the third embodiment. That is, for example, the bit line BL may include the aluminum wiring AL as in the third embodiment. The fourth embodiment of the present invention differs from the first embodiment only in each point described above. That is, all of the structures, conditions, procedures, effects, etc., not described above in the fourth embodiment are the same as those in the first embodiment.

### Fifth Embodiment

A fifth embodiment differs from the first embodiment in that a clad layer is provided in the wiring layer etc. in the normal MRAM having the digit line. The structure of the present embodiment is explained below.

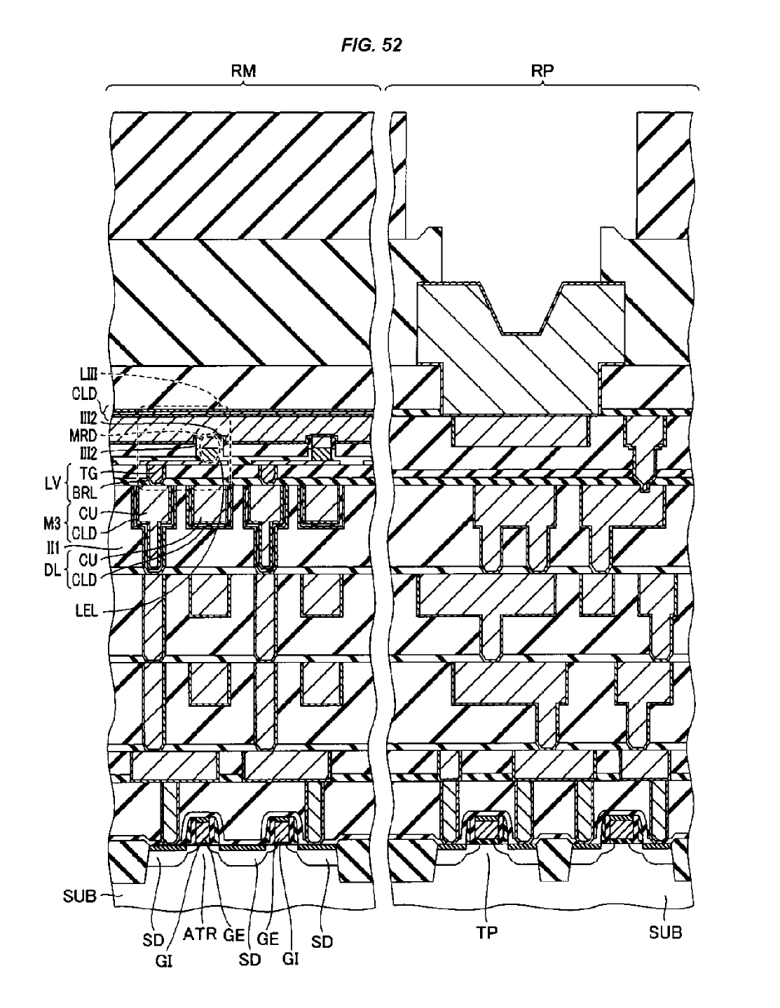

Referring to FIG. 52 to FIG. 54, in the memory cell of the normal MRAM of the present embodiment, the clad layer CLD (first clad layer) is formed on the side surface and top surface of the bit line BL.

As described above, the clad layer CLD has a three-layer structure in which the high permeability film MG having a high permeability is sandwiched by two layers of the barrier metal BRL. Then, the barrier metal BRL constituting the clad layer CLD is formed also on the bottom surface of the bit line BL.

In the present embodiment, as will be described later, in the wiring groove TR to constitute the bit line BL, the area of the bottom part thereof in a planar view is smaller than that of the top part thereof in a planar view. That is, the side surface of the bottom part of the wiring groove TR is formed outside at a distance substantially equal to the thickness of the sidewall insulating layer III2 with respect to the upper side surface of the magnetoresistive element MRD. Because of this, the aspect is such that the wiring groove TR in opposition to the upper side surface of the magnetoresistive element MRD at the bottom part is filled with the thin film of the sidewall insulating layer III2.

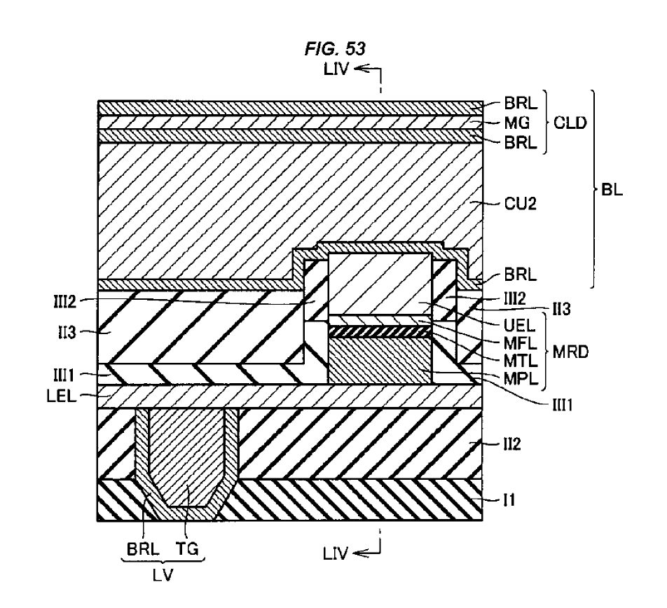

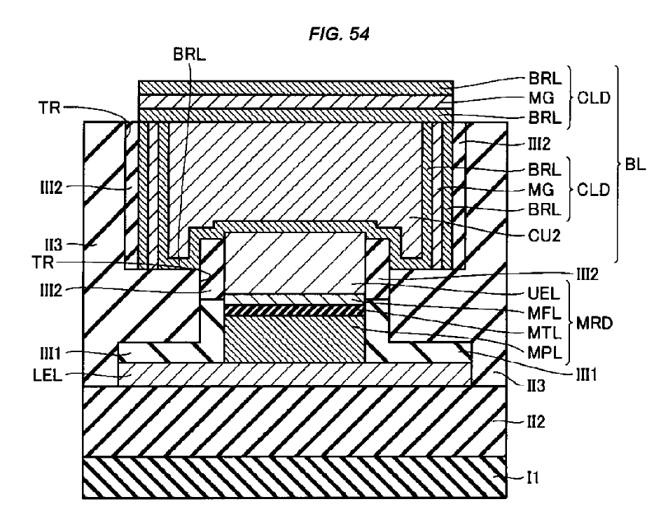

In FIG. 53 and FIG. 54, the bottom surface of the sidewall insulating layer III2 is located within the range of the height of the thickness of the sidewall of the free layer MFL. However, as in the other embodiments, the bottom surface of the sidewall insulating layer III2 may be located within the range of the height of the thickness of the sidewall of the pin layer MPL due to the variations at the time of the manufacturing step.

The clad layer CLD described above may be formed for the STT-MRAM. However, more preferably, the clad layer CLD is formed for the normal MRAM that uses a magnetic field shown in FIG. 10 to FIG. 12, FIG. 52 to FIG. 54.

The structure of the present embodiment shown in FIG. 52 to FIG. 54 differs from that in the first embodiment shown in FIG. 5 to FIG. 7 in the points described above and other points are the same as those of the structure in the first embodiment shown in FIG. 5 to FIG. 7, and therefore, the same symbol is attached to the same component and its explanation is not repeated.

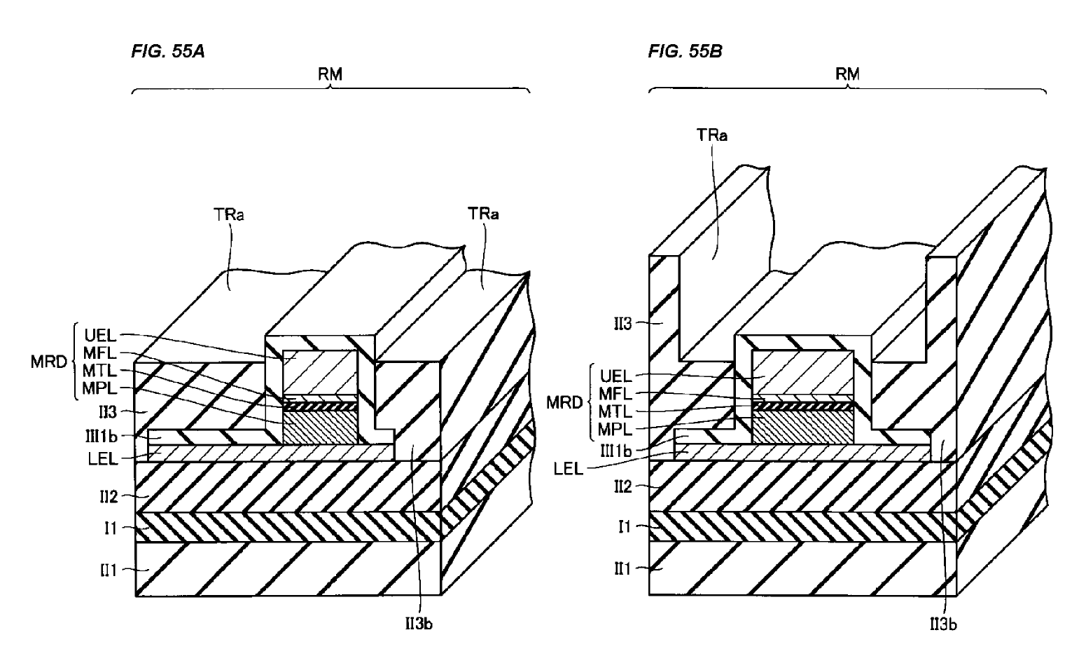

Next, the manufacturing method of the normal MRAM shown in FIG. 52 to FIG. 54 as a semiconductor device of the present embodiment is explained using FIG. 55 to FIG. 60. The following FIG. 55 to FIG. 60 show sectional views (A) when viewed in the same direction as that in FIG. 13 to FIG. 20 and sectional views (B) (sectional view along the XXI-XXI line in FIG. 20) when the magnetoresistive element MRD is cut in the direction perpendicular to that in FIG. 13 to FIG. 20.

Referring to FIG. 55, after the step shown in FIG. 20, the wiring groove TRa is formed as in FIG. 21. However, the wiring groove TRa here may be formed shallower than the wiring groove TRa in FIG. 21.

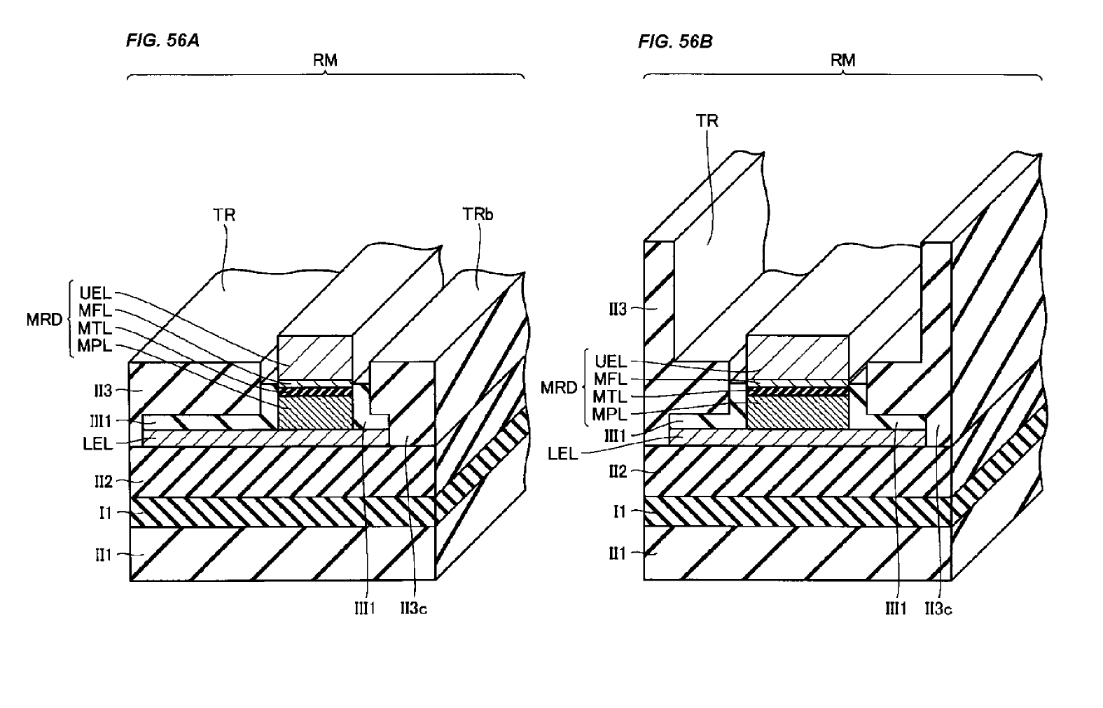

Referring to FIGS. 56(A) and 56(B), the same etching as that in FIG. 22 is performed and the wiring groove TR deeper than the wiring groove TRa is formed. However, here, it is preferable to perform etching so that the top surface of the silicon nitride film III1 is deeper than the bottom surface of the wiring groove TR. That is, preferably, the wiring groove TR has an aspect in which the width of the wiring groove TR is substantially the same as the thickness of the silicon nitride film III1 at the top part of the silicon nitride film III1.

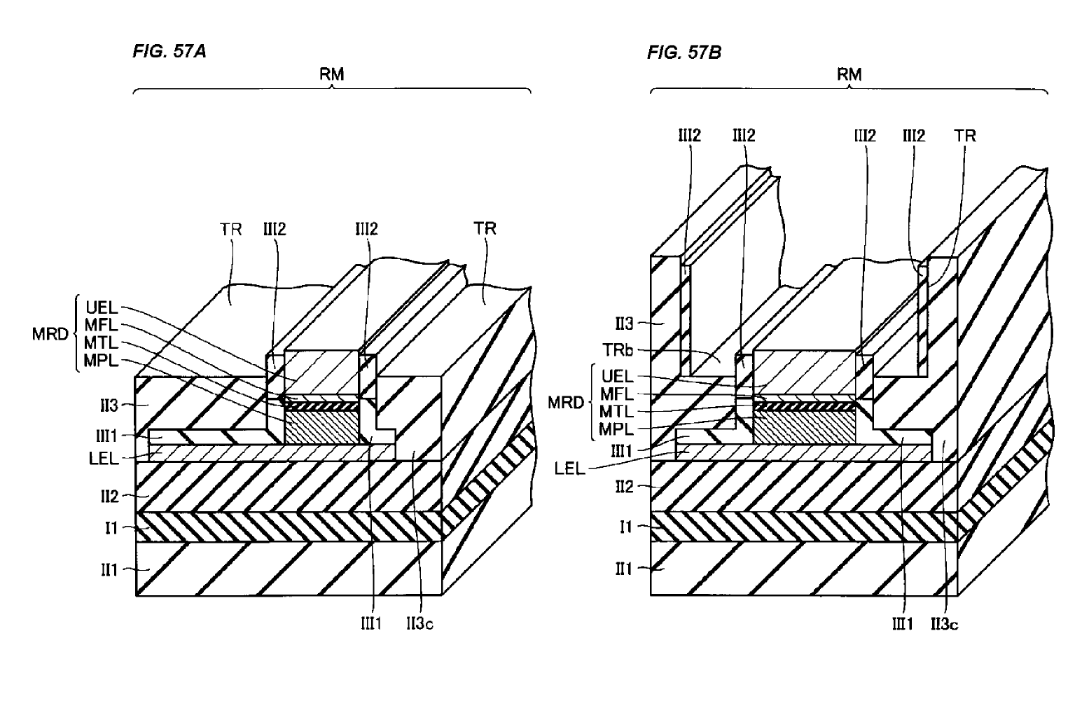

Referring to FIGS. 57(A) and 57(B), a silicon nitride film is formed as in FIG. 23 and the silicon nitride film is removed by etching as in FIG. 24. As a result of that, the sidewall insulating layer III2 is left on the side surface of the wiring groove TR and the upper side surface of the magnetoresistive element MRD. At this time, preferably, the sidewall insulating layer III2 on the upper side surface of the magnetoresistive element MRD is formed so as to contact the top surface of the lower insulating layer III1. That is, the bottom surface of the sidewall insulating layer III2 is arranged at the part lower than the bottom surface of the wiring groove TR.

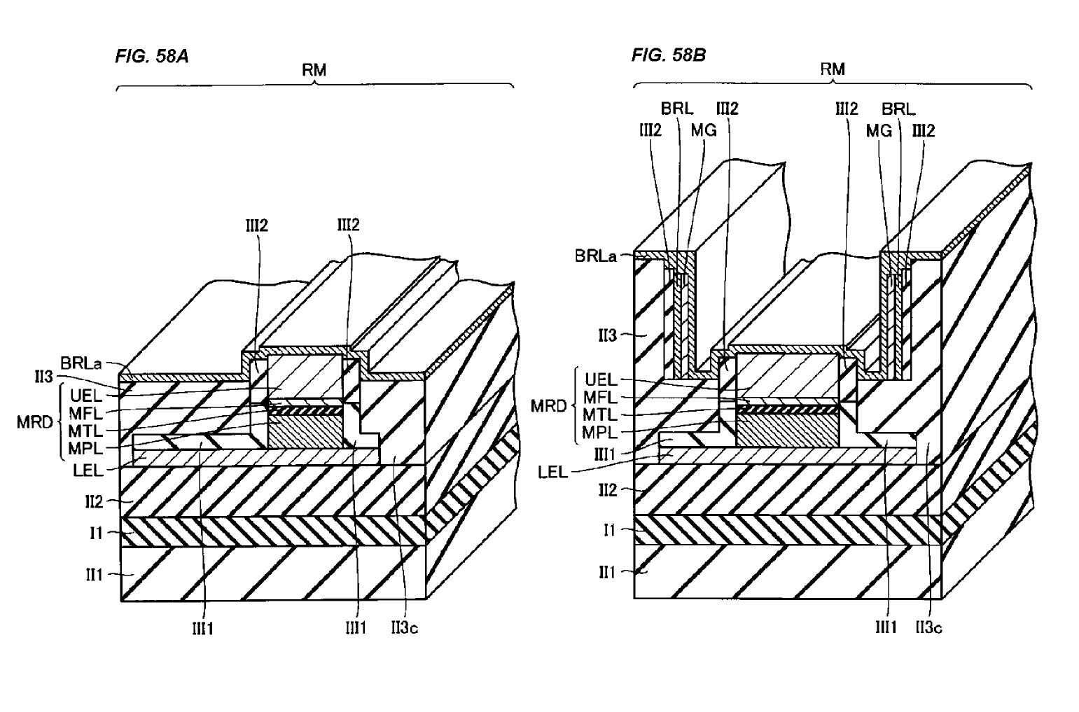

Referring to FIGS. 58(A) and 58(B), a barrier metal is formed on the top surface of the interlayer insulating layer II3 so as to cover the side surface and the bottom surface of the wiring groove TR. The barrier metal BRL is removed by, for example, the photoengraving technique and etching so that only the side surface of the wiring groove TR is left. However, the barrier metal BRL may be left over the bottom surface of the wiring groove TR and the top surface of the magnetoresistive element MRD. Next, a high permeability film is formed on the top surface of the interlayer insulating layer II3 so as to cover the side surface and the bottom surface of the wiring groove TR. The high permeability film MG is removed by, for example, the photoengraving technique and etching so that only the side surface of the wiring groove TR is left. After that, the barrier metal BRLa is further formed so as to cover the top surface of the high permeability film MG and cover over the bottom surface of the wiring groove TR and the top surface of the magnetoresistive element MRD.

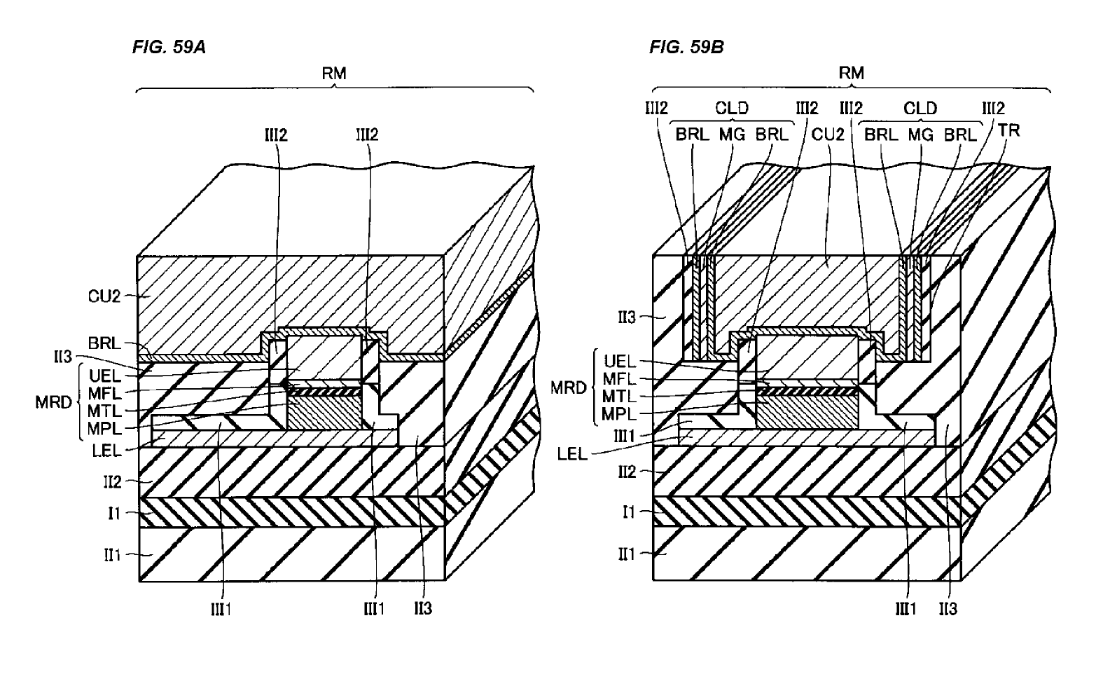

Referring to FIGS. 59(A) and 59(B), as in FIG. 26, FIG. 27, the copper film CU2 is formed so as to fill in the inside of the wiring groove TR and the copper film CU2a and the silicon oxide film II3 are subjected to chemical mechanical polishing processing until the top surface of the interlayer insulating layer II3 is exposed. The barrier metal BRL, the high permeability film MG, and the barrier metal BRL formed over the side surface of the wiring groove TR form the clad layer CLD.

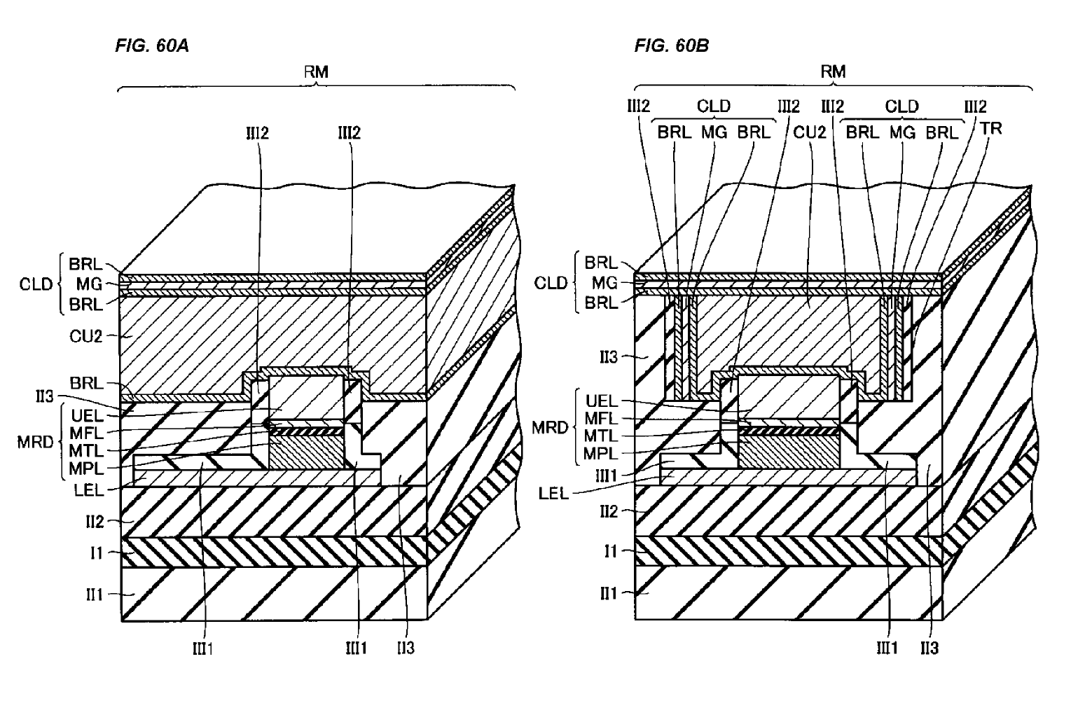

Referring to FIGS. 60(A) and 60(B), the barrier metal BRL, the high permeability film MG, the barrier metal BRL are laminated in this order over the surface having been subjected to chemical mechanical polishing processing in the step in FIG. 59. These layers are formed as the clad layer CLD that covers over the main surface of the copper film CU2. After that, by the photoengraving technique and etching technique, the bit line BL in the aspect shown in FIG. 53 and FIG. 54 is formed.

Next, the working and effect of the present embodiment are explained. The present embodiment has the following effect in addition to the working and effect in the first embodiment.

In particular, in the method of manufacturing the normal MRAM according to the present embodiment, a wiring groove is formed deep on the upper side surface of the magnetoresistive element MRD. Then, the sidewall insulating layer III1 is formed so as to fill in the deep, narrow wiring groove over the upper side surface. That is, the sidewall insulating layer III1 is arranged so as to be sandwiched between the interlayer insulating layer II3 and the magnetoresistive element MRD.

Because of this, the high permeability film MG of the clad layer CLD is suppressed from being formed or left over the upper side surface. Consequently, the high permeability film MG is prevented from being arranged over the upper side surface of the normal MRAM according to the present embodiment.

It is known that if the high permeability film MG is arranged around the free layer MFL of the magnetoresistive element MRD, the high permeability film MG affects the operation of the magnetoresistive element MRD. Because of this, by avoiding the high permeability film MG from being arranged in the vicinity of the side surface of the magnetoresistive element MRD, it is possible to further improve yields of the memory cell element RM.

It may also be possible to combine the structure of the present embodiment with that of the second embodiment or fourth embodiment. The fifth embodiment of the present invention differs from the first embodiment of the present invention only in each point described above. That is, all of the structures, conditions, procedures, effects, etc., not described in the fifth embodiment of the present invention are the same as those in the first embodiment of the present invention.

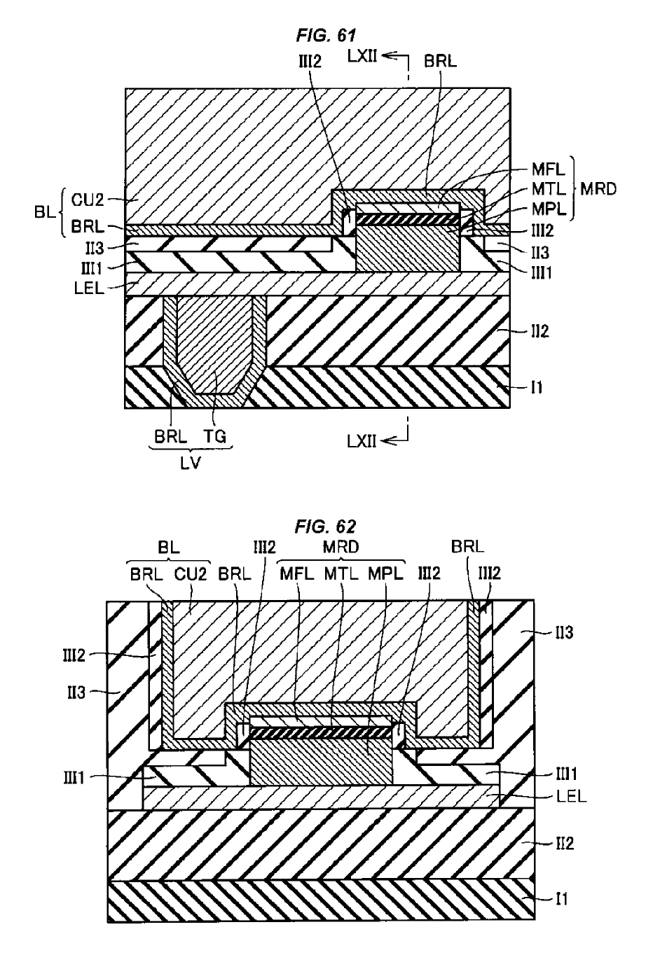

Referring to FIG. 61 and FIG. 62, it may also be possible for the magnetoresistive element MRD in each of the embodiments described above to have a structure in which the upper electrode UEL is not provided and the top surface of the free layer MFL contacts the bit line BL. The structure in FIG. 61 and FIG. 62 differs from that in FIG. 6 and FIG. 7 in that the upper electrode UEL is not formed on the top surface of the free MFL and other points are the same as those in FIG. 6 and FIG. 7, and therefore, the same symbol is attached to the same component and its explanation is not repeated.

It should be considered that the embodiments disclosed above are mere illustrations in all the points and not limitative. The scope of the present invention is defined by claims not by the explanations given above and it is intended to include all modifications in the meaning and scope equivalent to those of claims.

The present invention can be applied particularly advantageously to a semiconductor device having a magnetoresistive element and its manufacturing method.

What is claimed is:

1. A semiconductor device comprising:
a semiconductor substrate having a main surface;
a magnetoresistive element located over the main surface of the semiconductor substrate and including a pin layer, a tunnel insulating layer, and a free layer;
a lower insulating layer contacting a lower side surface of the magnetoresistive element;
a sidewall insulating layer located over the lower insulating layer in contact with an upper side surface of the magnetoresistive element and exposing a top surface of the magnetoresistive element; and
a conductive layer contacting the top surface of the magnetoresistive element exposed from the sidewall insulating layer.

2. The semiconductor device according to claim 1,
wherein the conductive layer is a first wiring layer extending in a direction along the main surface.

3. The semiconductor device according to claim 1, further comprising a first wiring layer extending in a direction along the main surface above the magnetoresistive element,
wherein the conductive layer is a coupling conductive layer for electrically coupling the magnetoresistive element and the first wiring layer.

4. The semiconductor device according to claim 1,
wherein the sidewall insulating layer contacts a side surface of the tunnel insulating layer of the magnetoresistive element.

5. The semiconductor device according to claim 1,
wherein the magnetoresistive element includes an upper electrode having the top surface of the magnetoresistive element.

6. The semiconductor device according to claim 1, further comprising:
a lower electrode coupled to an undersurface on the opposite side of the top surface of the magnetoresistive element; and
an interlayer insulating layer formed on an upper side of the lower electrode,
wherein the lower insulating layer is a protection insulating layer disposed between the lower electrode and the interlayer insulating layer.

7. The semiconductor device according to claim 1, further comprising a lower electrode coupled to an undersurface on the opposite side of the top surface of the magnetoresistive element,
wherein the lower electrode is disposed only in a position that substantially overlaps the magnetoresistive element in a planar view.

8. The semiconductor device according to claim 2, further comprising a second wiring layer for inverting magnetization of the free layer below the magnetoresistive element.

9. The semiconductor device according to claim 8, further comprising:
a first clad layer formed on a side surface and a top surface of the first wiring layer to shield a magnetic field; and
a second clad layer formed on a side surface and a bottom surface of the second wiring layer.

10. A manufacturing method of a semiconductor device, comprising:
providing a semiconductor substrate having a main surface;
forming a magnetoresistive element that is located over the main surface of the semiconductor substrate and includes a pin layer, a tunnel insulating layer, and a free layer;
forming a first insulating layer so as to cover the magnetoresistive element;
removing the first insulating layer by an amount corresponding to a predetermined thickness to expose a top surface and an upper side surface of the magnetoresistive element from the first insulating layer;
forming a second insulating layer so as to cover the top surface and the upper side surface of the magnetoresistive element exposed from the first insulating layer;
forming a sidewall insulating layer in contact with the upper side surface of the magnetoresistive element from the second insulating layer by etching the second insulating layer until the top surface of the magnetoresistive element is exposed; and
forming a conductive layer so as to contact the top surface of the magnetoresistive element exposed from the sidewall insulating layer.

11. The manufacturing method of a semiconductor device according to claim 10, further comprising, before the forming the first insulating layer, forming a third insulating layer so as to cover the top surface and the side surface of the magnetoresistive element,
wherein the forming the first insulating layer includes the forming the first insulating layer so as to cover the magnetoresistive element and the third insulating layer, and
wherein the exposing the top surface and the upper side surface of the magnetoresistive element from the first insulating layer includes:
exposing the third insulating layer from the first insulating layer by removing the first insulating layer; and
exposing the top surface and the upper side surface of the magnetoresistive element from the first and third insulating layers while leaving the third insulating layer so as to contact the lower side surface of the magnetoresistive element by removing the third insulating layer exposed from the first insulating layer by a predetermined amount.

12. The manufacturing method of a semiconductor device according to claim 10, further comprising: forming a lower electrode located over the main surface of the semiconductor substrate,
wherein the forming the magnetoresistive element includes the forming the magnetoresistive element so that the lower surface of the magnetoresistive element contacts the lower electrode, and
wherein the lower electrode is formed only in a position that substantially overlaps the magnetoresistive element in a planar view.

13. The manufacturing method of a semiconductor device according to claim 10,
wherein the removing the first insulating layer by an amount corresponding to a predetermined thickness includes the forming a wiring groove to expose the top surface and the upper side surface of the magnetoresistive element from the first insulating layer on the top surface of the first insulating layer, and
wherein the forming the conductive layer includes the forming a first wiring layer extending in the direction along the main surface within the wiring groove as the conductive layer.

14. The manufacturing method of a semiconductor device according to claim 10,
wherein the removing the first insulating layer by an amount corresponding to a predetermined thickness includes the forming a coupling groove to expose the top surface and the upper side surface of the magnetoresistive element from the first insulating layer on the top surface of the first insulating layer, and
wherein the forming the conductive layer includes the forming a coupling conductive layer within the coupling groove as the conductive layer and further includes the forming, over the conductive layer, a first wiring layer that is electrically coupled to the coupling conductive layer and extends in the direction along the main surface.

15. The manufacturing method of a semiconductor device according to claim 10,
wherein the removing the first insulating layer by an amount corresponding to a predetermined thickness includes the removing the entire top surface of the first insulating layer by an amount corresponding to a predetermined thickness to expose the top surface and the upper side surface of the magnetoresistive element from the first insulating layer, and
wherein the forming the conductive layer includes:
forming a conductive material so as to cover the first insulating layer and the magnetoresistive element; and
forming the conductive layer from the conductive material by selectively removing and patterning the conductive material.
